(19) United States
(12) Patent Application Publication
(10) Pub. No.: US 2026/0247811 A1
(43) Pub. Date: Aug. 20, 2026

(54) DISPLAY DEVICE

(71) Applicant: Sharp Display Technology Corporation, Kameyama City, Mie (JP)

(72) Inventors: Tohru OKABE, Kameyama City (JP); Shoji OKAZAKI, Kameyama City (JP); Shinji ICHIKAWA, Kameyama City (JP); Hiroki TANIYAMA, Kameyama City (JP); Eiji FUJIMOTO, Kameyama City (JP)

(21) Appl. No.: 19/145,034

(22) PCT Filed: Jan. 5, 2023
(86) PCT No.: PCT/JP2023/000072

§ 371 Date: Jul. 1, 2025

(51) Int. Cl. H10K 59/131; H10K 59/12; H10K 59/121; H10K 59/65; H10K 59/80

(52) U.S. Cl. CPC H10K 59/131; H10K 59/1201; H10K 59/121; H10K 59/65; H10K 59/871

(57) ABSTRACT

A display device includes a display region and a frame region, wherein the display region is provided with a light-emitting element, a pixel circuit configured to control light emission of the light-emitting element, and a connection wiring line connecting the pixel circuit and the light-emitting element, the connection wiring line includes a plurality of partial wiring lines formed in different layers with a corresponding one of a plurality of organic insulating films interposed between adjacent ones of the plurality of partial wiring lines, the frame region is provided with a frame wiring line that is exposed from the organic insulating films, and an inorganic insulating film that covers the frame wiring line, and a protection film is provided in a layer below the inorganic insulating film in a manner that the protection film covers an end surface of the frame wiring line in a width direction.

### TECHNICAL FIELD

The disclosure relates to a display device.

### BACKGROUND ART

In recent years, organic electro luminescence (hereinafter, referred to as EL) display devices using organic EL elements have been used in practical applications. In a case where the organic EL display device is used as a display of an information terminal such as a smartphone or a tablet terminal, or in a case where the organic EL display device is used as a display for performing bidirectional communication such as a video telephone call or a video conference, the organic EL display device is combined with a camera that captures an image of the front face side where the captured image is displayed, that is, combined with a so-called in-camera.

In such an organic EL display device provided with an in-camera, it is proposed to dispose a camera on the back face side of the organic EL display device in a position overlapping a display region in a plan view. An example of such an organic EL display device is disclosed in PTL 1.

### CITATION LIST

### Patent Literature

PTL 1: JP 2022-041886 A

### SUMMARY

### Technical Problem

In a display region and a frame region provided around the display region in the organic EL display device, various wiring lines used for controlling image display are provided. A predetermined wiring line located in the display region is covered with an organic insulating film made of a photosensitive resin. The organic insulating film is at least partially removed in the frame region in order to prevent moisture from entering the display region. For this reason, a frame wiring line located in the frame region is exposed from the organic insulating film, but is covered and protected by an inorganic insulating film.

Furthermore, an organic EL display device with an in-camera has a first display region that forms a general display portion, and a second display region inside the first display region that transmits external light used by the camera. The second display region is provided with a connection wiring line that connects an organic EL element and a pixel circuit. For such a connection wiring line, a multilayer structure in which a plurality of partial wiring lines configuring the wiring line and a plurality of organic insulating films are alternately layered is preferably adopted because it is advantageous in increasing the degree of freedom of layout.

In the organic EL display device, various wiring lines are often composed of a layered film in which a plurality of conductive layers are layered. As the layered film, for example, a structure in which a titanium layer, an aluminum layer, and a titanium layer are layered in this order is preferably adopted. However, in such a case, the frame wiring line exposed from the organic insulating film is exposed to a developing solution for developing a photosensitive resin every time the organic insulating film of each layer included in the above-described multilayer structure of the connection wiring line is formed.

At this time, when an alkaline developing solution is used, the aluminum layer of the frame wiring line is side-etched to intrude beneath the titanium layer provided thereon. As a result, the titanium layer on the upper side of the frame wiring line protrudes laterally to form an eaves-like portion in the frame wiring line. In this case, the side end surface of the frame wiring line cannot be suitably covered with the inorganic insulating film, and a gap is formed between the aluminum layer and the inorganic insulating film at the side portion of the frame wiring line. This gap can serve as a path through which moisture enters the display region from the outside. When moisture enters the gap and enters the display region through the frame wiring line, deterioration of the organic EL element (in particular, a light-emitting functional layer) is caused and the reliability of the organic EL display device is reduced.

An object of the disclosure is to prevent moisture from entering a display region through a frame wiring line.

### Solution to Problem

The disclosure is intended to be applied to a display device. A display device according to the technology of the disclosure includes a display region in which an image is displayed and a frame region provided around the display region. In the display region, a light-emitting element, a pixel circuit that controls light emission of the light-emitting element, and a connection wiring line that connects the pixel circuit and the light-emitting element are provided. The connection wiring line includes a plurality of partial wiring lines formed in different layers with a corresponding one of a plurality of organic insulating films interposed between adjacent ones of the plurality of partial wiring lines. The plurality of partial wiring lines and the plurality of organic insulating films constitute a multilayer structure in which the plurality of partial wiring lines and the plurality of organic insulating films are alternately layered. The frame region is provided with a frame wiring line that is located in a layer below a part or entirety of the multilayer structure and is exposed from the organic insulating films, and an inorganic insulating film that is located in a layer above the multilayer structure and covers the frame wiring line. The frame wiring line is composed of a layered film in which a first metal layer made of any one metal of aluminum, copper, silver, and gold or an alloy of any of the metals and a second metal layer made of any one metal of titanium, molybdenum, chromium, and tantalum or an alloy of any of the metals are sequentially layered. A protection film is provided in a layer below the inorganic insulating film so as to cover an end surface of the frame wiring line in a width direction.

### Advantageous Effects of Disclosure

According to a display device of the disclosure, it is possible to prevent moisture from entering a display region through a frame wiring line.

### BRIEF DESCRIPTION OF DRAWINGS

FIG. 1 is a plan view illustrating a schematic configuration of an organic EL display device according to a first embodiment.

FIG. 2 is a cross-sectional view of the organic EL display device taken along line II-II in FIG. 1.

FIG. 3 is a plan view illustrating pixels and various wiring lines in a first display region of the organic EL display device.

FIG. 4 is a cross-sectional view of the first display region of the organic EL display device taken along line IV-IV in FIG. 3.

FIG. 5 is an equivalent circuit diagram illustrating an example of a pixel circuit.

FIG. 6 is a plan view illustrating an example of a schematic configuration of a second display region of the organic EL display device and its surroundings.

FIG. 7 is a plan view illustrating an example of a main portion of the organic EL display device surrounded by line VII in FIG. 6.

FIG. 8 is a cross-sectional view of the main portion of the organic EL display device taken along line VIII-VIII in FIG. 7.

FIG. 9 is a cross-sectional view of the main portion of the organic EL display device taken along line IX-IX in FIG. 7.

FIG. 10 is a plan view illustrating the main portion of the organic EL display device surrounded by line X in FIG. 1.

FIG. 11 is a cross-sectional view of the main portion of the organic EL display device taken along line XI-XI in FIG. 10.

FIG. 12 is a cross-sectional view of the main portion of the organic EL display device taken along line XII-XII in FIG. 10.

FIG. 13 is a cross-sectional view illustrating a part of a manufacturing process of the organic EL display device according to the first embodiment.

FIG. 14 is a cross-sectional view illustrating a part of the manufacturing process of the organic EL display device according to the first embodiment.

FIG. 15 is a cross-sectional view illustrating a part of the manufacturing process of the organic EL display device according to the first embodiment.

FIG. 16 is a cross-sectional view illustrating a part of the manufacturing process of the organic EL display device according to the first embodiment.

FIG. 17 is a cross-sectional view illustrating a part of the manufacturing process of the organic EL display device according to the first embodiment.

FIG. 18 is a cross-sectional view illustrating a part of the manufacturing process of the organic EL display device according to the first embodiment.

FIG. 19 is a cross-sectional view illustrating a part of the manufacturing process of the organic EL display device according to the first embodiment.

FIG. 20 is a cross-sectional view illustrating a part of the manufacturing process of the organic EL display device according to the first embodiment.

FIG. 21 is a cross-sectional view illustrating a part of the manufacturing process of the organic EL display device according to the first embodiment.

FIG. 22 is a cross-sectional view illustrating a part of the manufacturing process of the organic EL display device according to the first embodiment.

FIG. 23 is a cross-sectional view illustrating a part of the manufacturing process of the organic EL display device according to the first embodiment.

FIG. 24 is a cross-sectional view illustrating a part of the manufacturing process of the organic EL display device according to the first embodiment.

FIG. 25 is a cross-sectional view illustrating a part of the manufacturing process of the organic EL display device according to the first embodiment.

FIG. 26 is a cross-sectional view illustrating a part of the manufacturing process of the organic EL display device according to the first embodiment.

FIG. 27 is a cross-sectional view illustrating a part of the manufacturing process of the organic EL display device according to the first embodiment.

FIG. 28 is a cross-sectional view illustrating a part of the manufacturing process of the organic EL display device according to the first embodiment.

FIG. 29 is a cross-sectional view of a portion corresponding to FIG. 12 of an organic EL display device according to a second embodiment.

FIG. 30 is a cross-sectional view illustrating a part of a manufacturing process of the organic EL display device according to the second embodiment.

FIG. 31 is a cross-sectional view illustrating a part of the manufacturing process of the organic EL display device according to the second embodiment.

FIG. 32 is a cross-sectional view of a portion corresponding to FIG. 9 of an organic EL display device according to a third embodiment.

FIG. 33 is a cross-sectional view of a portion corresponding to FIG. 12 of the organic EL display device according to the third embodiment.

FIG. 34 is a cross-sectional view illustrating a part of a manufacturing process of the organic EL display device according to the third embodiment.

FIG. 35 is a cross-sectional view of a portion corresponding to FIG. 12 of an organic EL display device according to a second modification example.

FIG. 36 is a plan view of a portion corresponding to FIG. 10 illustrating an aspect of an organic EL display device according to a third modification example.

FIG. 37 is a cross-sectional view of a portion corresponding to FIG. 10 illustrating another aspect of the organic EL display device according to the third modification example.

FIG. 38 is a cross-sectional view illustrating a portion of a manufacturing process of an organic EL display device according to a comparative example.

FIG. 39 is a cross-sectional view of a portion corresponding to FIG. 12 of the organic EL display device according to the comparative example.

FIG. 40 is a plan view of a portion corresponding to FIG. 10 of the organic EL display device according to the comparative example.

### DESCRIPTION OF EMBODIMENTS

Exemplary embodiments will be described below in detail with reference to the drawings. In the embodiments described below, an organic EL display device is described as an example of a display device according to the disclosure. The drawings are for schematically describing the technology of the disclosure. Thus, in the drawings, dimensions, ratios, or numbers may be exaggerated or simplified to facilitate the technology of the disclosure.

In the following embodiments, a “first direction” means a horizontal direction of a screen of a display device oriented in a predetermined use state. A “second direction” is a direction orthogonal to the first direction and means a vertical direction of the screen of the display device oriented in a predetermined use state. A row of constituent elements such as subpixels means a horizontal arrangement of a plurality of constituent elements forming a line in the first direction. A column of constituent elements such as subpixels means a vertical arrangement of a plurality of constituent elements forming a line in the second direction.

In the following embodiments, a description that, on a constituent element such as a certain film, layer or element, a constituent element such as another film, layer or element is provided or formed means not only a case where another constituent element is present directly above the certain constituent element but also a case where a constituent element such as still another film, layer, or element is interposed between both the constituent elements.

In the following embodiments, a description that a certain constituent element is connected to another constituent element means that the constituent elements are electrically connected unless otherwise specified. This description means, without departing from the gist of the technology of the disclosure, not only a case where the constituent elements are directly connected but also a case where the constituent elements are indirectly connected with still another constituent element interposed therebetween. The description also includes a case where a certain constituent element is integrated with another constituent element, that is, a part of the certain constituent element constitutes the other constituent element.

In the following embodiments, a description that a certain constituent element and another constituent element are in the same layer means that the certain constituent element and the other constituent element are formed by the same process. A description that a certain constituent element is in a layer below another constituent element means that the certain constituent element is formed by a process earlier than that of the other constituent element. A description that a certain constituent element is in an upper layer above another constituent element means that the certain constituent element is formed by a process later than that of the other constituent element.

In the following embodiments, a description that a certain constituent element is the same as or equivalent to another constituent element includes not only a state where the certain constituent element is completely the same as or completely equivalent to the other constituent element, but also a state where the certain constituent element is substantially the same as or substantially equivalent to the other constituent element, such as a state where the certain constituent element and the other constituent element vary within a range of a manufacturing variation, tolerance, or the like.

In the following embodiments, descriptions of first, second, third, etc. are used to distinguish the words and phrases to which these descriptions are given, and no limitation with regard to the number and order of the words and phrases is intended.

### First Embodiment

An organic EL display device 1 according to this embodiment is used as a display for mobile devices such as multi-function phones known as smartphones and tablet terminals. The organic EL display device 1 may also be used as a display for various other devices such as personal computers (PCs) and television sets.

### Configuration of Organic EL Display Device

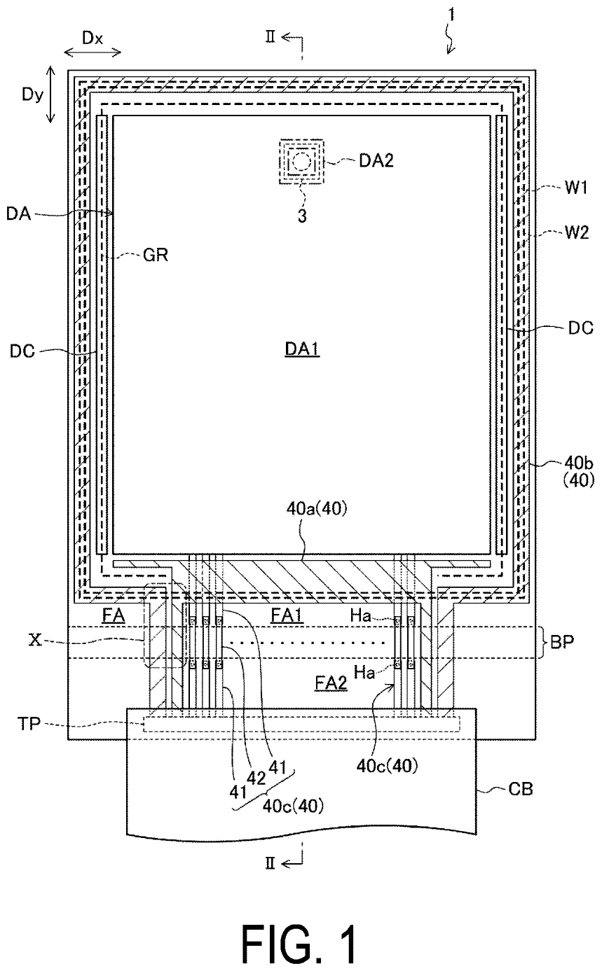

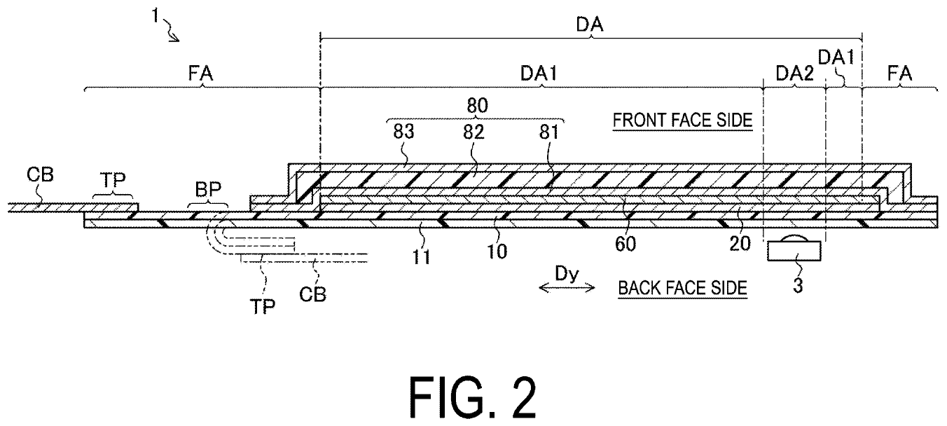

As illustrated in FIGS. 1 and 2, the organic EL display device 1 constitutes a display device with an in-camera, and includes a camera 3 that captures an image of a front face side of a screen.

The camera 3 is disposed on the back face side of a substrate layer 10 that constitutes the organic EL display device 1 in a position overlapping a display region DA in a plan view. The camera 3 is an example of an electronic component that utilizes light. The camera 3 includes an image sensor such as a charge coupled device (CCD) and uses external light transmitted through the display region DA. The camera 3 is installed inside a housing (not illustrated) that accommodates the organic EL display device 1.

### Schematic Configurations of Display Region and Frame Region

The organic EL display device 1 includes the display region DA and a frame region FA.

The display region DA is a region in which an image is displayed and constitutes a screen. The display region DA is provided in a rectangular shape, for example. The display region DA may have a substantially rectangular shape such as a shape in which at least one side is arc-shaped, a shape in which at least one corner is arc-shaped or a shape in which a cutout portion is formed in at least one side, or may have any other shape.

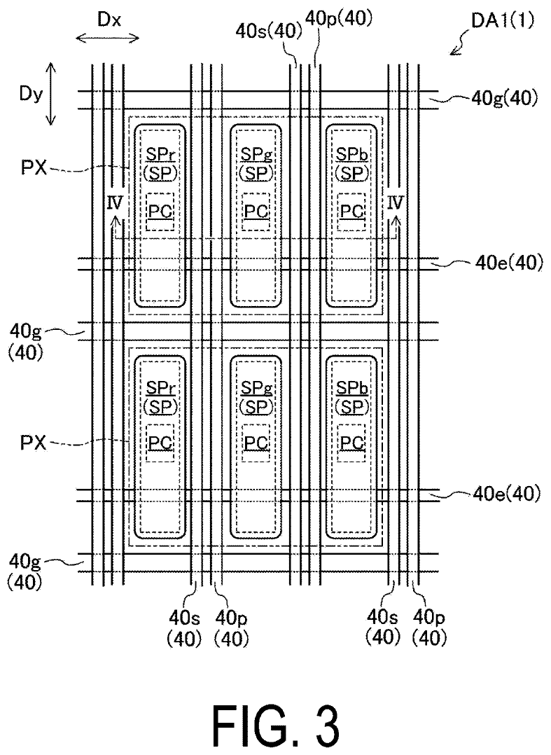

The display region DA includes a first display region DA1 and a second display region DA2. The first display region DA1 is a region that occupies most of the display region DA. As illustrated in FIG. 3, the first display region DA1 is composed of a plurality of pixels PX. The plurality of pixels PX are arrayed in a matrix.

Each pixel PX is composed of three subpixels SP. The three subpixels SP are a subpixel SPr for emitting red light, a subpixel SPg for emitting green light, and a subpixel SPb for emitting blue light. These three subpixels SPr, SPg, and SPb are arrayed in a stripe shape, for example. The second display region DA2 is also configured to include a plurality of pixels PX.

As illustrated in FIG. 1, the second display region DA2 is provided inside the first display region DA1. The second display region DA2 is a region that transmits external light to be used by the camera 3. The second display region DA2 is provided, for example, in a rectangular shape at a position near the outer periphery of the display region DA (at an upper position in FIG. 1). The second display region DA2 may have another shape such as a circular shape or an elliptical shape.

The frame region FA is a region that constitutes a non-display portion other than the screen. The frame region FA is provided around the display region DA in, for example, a rectangular frame shape. The frame region FA may be in a frame shape other than a rectangle. The frame region FA includes a terminal portion TP and a bending portion BP.

The terminal portion TP is a portion for connecting to an external circuit. The terminal portion TP is provided at a position close to an outer edge of a portion that constitutes one side of the frame region FA in such a manner as to extend in a first direction Dx along the one side. The terminal portion TP includes a plurality of terminals (not illustrated). To the terminal portion TP, a wiring board CB such as a flexible printed circuit (FPC) is connected.

The bending portion BP is provided between the terminal portion TP and the display region DA, and extends horizontally across the entire frame region FA in the first direction Dx. The frame region FA is bent at the bending portion BP, for example, by approximately 180°, so as to form a U-shape (illustrated by two-dot chain lines in FIG. 2). Accordingly, the terminal portion TP is disposed on the back face side of the organic EL display device 1.

In the frame region FA, a trench GR is formed in a flattening film 50 to be described below in a substantially C-shape opening on the terminal portion TP side in a plan view so as to surround the display region DA. The trench GR penetrates the flattening film 50 and divides the flattening film 50 into the inside and outside of the frame region FA. The trench GR serves to prevent moisture from entering the display region DA from outside the frame region FA.

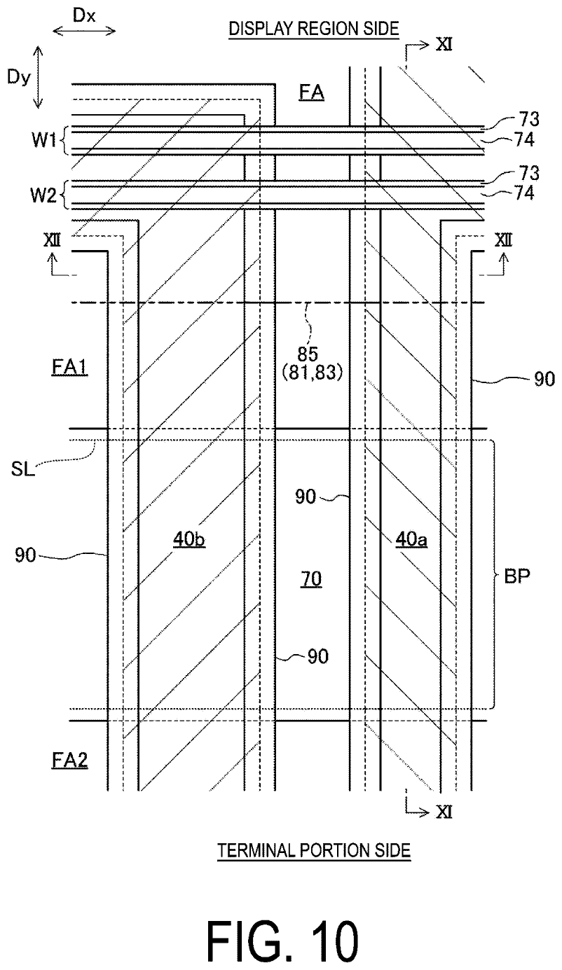

In the frame region FA, there are provided a drive circuit DC, a first frame wiring line 40a (for convenience, hatched by left upward diagonal lines in FIG. 1; similarly applied to FIG. 10 and the like), a second frame wiring line 40b (for convenience, hatched by right upward diagonal lines in FIG. 1; similarly applied to FIG. 10 and the like), a plurality of pull-out wiring lines 40c, a first dam wall W1, and a second dam wall W2. Both the first frame wiring line 40a and the second frame wiring line 40b are power supply trunk lines for applying a voltage to organic EL elements 65.

In the frame region FA, the drive circuit DC is disposed in a portion that constitutes a side (a left or right side in FIG. 1) adjacent to a side where the terminal portion TP is provided. The drive circuit DC is monolithically formed as a part of the TFT layer 20 described below. The drive circuit DC includes a gate driver and an emission driver.

The drive circuit DC is disposed across both sides (the display region DA side and the outer peripheral side of the frame region FA) of the trench GR in the width direction of the frame region FA. The drive circuit DC or a part thereof (a gate driver or an emission driver) is disposed on the outer peripheral side of the frame region FA rather than the trench GR. The drive circuit DC may be disposed on the display region DA side rather than the trench GR.

The first frame wiring line 40a is provided to extend in the first direction Dx with a large width in the opening portion of the trench GR. Both end portions of the first frame wiring line 40a on the display region DA side extend further to the display region DA side than the trench GR. Both end portions of the first frame wiring line 40a on the terminal portion TP side extend to the terminal portion TP. A high-level power supply voltage (ELVDD) is supplied to the first frame wiring line 40a at the terminal portion TP via a wiring board CB.

The second frame wiring line 40b is provided in a substantially C shape outside the trench GR so as to surround the display region DA2. Both end portions of the second frame wiring line 40b extend to the terminal portion TP along the first frame wiring line 40a. A low-level power supply voltage (ELVSS) is supplied to the second frame wiring line 40b at the terminal portion TP via the wiring board CB.

The first dam wall W1 is formed in a frame shape extending around the outer periphery of the trench GR so as to surround the display region DA. The second dam wall W2 is formed in a frame shape around the outer periphery of the first dam wall W1 so as to surround the display region DA, and is positioned at a distance from the first dam wall W1 in the width direction of the frame region FA. The first dam wall W1 and the second dam wall W2 prevent a liquid material (organic resin material) that forms an organic film 82 to be described below from spreading outside the frame region FA when the liquid material is applied during the manufacturing process of the organic EL display device 1.

Each of the plurality of pull-out wiring lines 40c is pulled out from the display region DA to the terminal portion TP. Each pull-out wiring line 40c extends to pass through the lower layers of the first frame wiring line 40a, the first dam wall W1 and the second dam wall W2. Each pull-out wiring line 40c is connected to a source wiring line 40s to be described below on the display region DA side. Each pull-out wiring line 40c is composed of a pair of lower layer pull-out wiring lines 41 and an upper layer pull-out wiring line 42.

The pair of lower layer pull-out wiring lines 41 is divided into a first portion FA1 between the display region DA and the bending portion BP and a second portion FA2 between the bending portion BP and the terminal portion TP. The plurality of lower layer pull-out wiring lines 41 in the first portion FA1 and the plurality of lower layer pull-out wiring lines 41 in the second portion FA2 are disposed to be spaced apart from each other in the first direction Dx and extend in parallel to each other in a second direction Dy.

The plurality of upper layer pull-out wiring lines 42 extend parallel to each other in the second direction Dy over a filling layer 70 to be described below so as to straddle the bending portion BP, and are spaced apart from each other in the first direction Dx. Each upper layer pull-out wiring line 42 is connected to a pair of lower layer pull-out wiring lines 41 positioned on both sides of the bending portion BP in the second direction Dy via first contact holes Ha formed in an interlayer insulating film 30 to be described below.

Layered Structure of Organic EL Display Device The organic EL display device 1 controls the light emission of each subpixel SP by a thin film transistor (hereinafter referred to as TFT) 45, and displays an image by the operation of the TFT 45. As illustrated in FIG. 2, the organic EL display device 1 includes a substrate layer 10, a TFT layer (thin film transistor layer) 20, a light-emitting element layer 60, and a sealing film 80.

### Substrate Layer

The substrate layer 10 is a layer forming a base of the organic EL display device 1. The substrate layer 10 is an example of a substrate. The substrate layer 10 has both light transmittance (which refers to transparency of visible light in this example; the same applies hereinafter) and flexibility. The substrate layer 10 is formed of an organic resin material such as a polyimide resin, a polyamide resin, or an epoxy resin. A protection film 11 having light transmittance is bonded to the back face of the substrate layer 10.

### TFT Layer

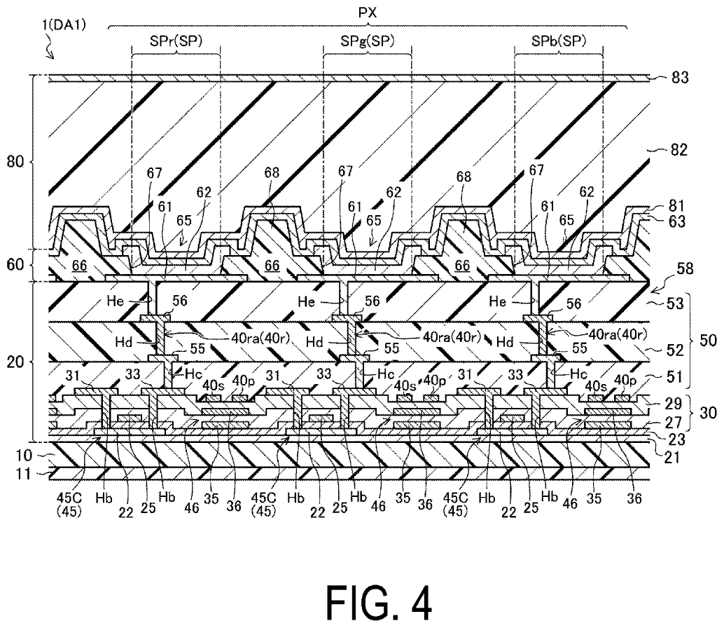

The TFT layer 20 is provided on the substrate layer 10. In addition to the drive circuit DC described above, the TFT layer 20 further includes various wiring lines 40 and a plurality of pixel circuits PC illustrated in FIG. 3. The drive circuit DC, the various wiring lines 40, and the pixel circuits PC are provided on a base coat film 21 illustrated in FIG. 4. The base coat film 21 is provided over the substantially entire surface of the substrate layer 10.

The various wiring lines 40 include the first frame wiring line 40a, the second frame wiring line 40b, and the plurality of pull-out wiring lines 40c described above, and also include a plurality of gate wiring lines 40g, a plurality of light emission control wiring lines 40e, a plurality of power supply wiring lines 40p, and a plurality of source wiring lines 40s. The various wiring lines 40 also include a plurality of connection wiring lines 40r to be described below.

The gate wiring lines 40g, the light emission control wiring lines 40e, the power supply wiring lines 40p, the source wiring lines 40s, and the connection wiring lines 40r are provided in the display region DA. Here, the source wiring line 40s is an example of a signal wiring line.

Each of the plurality of gate wiring lines 40g is a wiring line for supplying a gate signal to the pixel circuit PC. The plurality of gate wiring lines 40g are disposed to be spaced apart from each other in the second direction Dy in the display region DA, and extend in parallel to each other in the first direction Dx. The gate wiring line 40g is provided for each row of the subpixels SP. Each of the gate wiring lines 40g is connected to the gate driver of the drive circuit DC.

Each of the plurality of light emission control wiring lines 40e is a wiring line for supplying an emission signal to the pixel circuit PC. The plurality of light emission control wiring lines 40e are disposed to be spaced apart from each other in the second direction Dy in the display region DA, and extend in parallel to each other in the first direction Dx. The light emission control wiring line 40e is provided for each row of the subpixels SP. Each of the light emission control wiring lines 40e is connected to the emission driver of the drive circuit DC.

Each of the plurality of power supply wiring lines 40p is a wiring line for supplying a predetermined high-level power supply voltage (ELVDD) to the pixel circuit PC. The plurality of power supply wiring lines 40p are disposed to be spaced apart from each other in the first direction Dx in the display region DA, and extend in parallel to each other in the second direction Dy. The power supply wiring line 40p is provided for each row of the subpixels SP. Each power supply wiring line 40p is connected to the first frame wiring line 40a.

Each of the plurality of source wiring lines 40s is a wiring line for transmitting a source signal to the pixel circuit PC. The plurality of source wiring lines 40s are disposed to be spaced apart from each other in the first direction Dx in the display region DA, and extend in parallel to each other in the second direction Dy. The source wiring line 40s is provided for each row of the subpixels SP. Each of the source wiring lines 40s is connected to a display control circuit (source driver) via the pull-out wiring line 40c and the wiring board CB.

The gate wiring lines 40g, the light emission control wiring lines 40e, and the lower layer pull-out wiring lines 41 are formed of, for example, the same material and in the same layer as gate electrodes 25 and first capacitance electrodes 47 to be described below. The power supply wiring lines 40p, the source wiring lines 40s, and the upper layer pull-out wiring lines 42 are formed of the same material and in the same layer as first and second terminal electrodes 31 and 33 to be described below, for example.

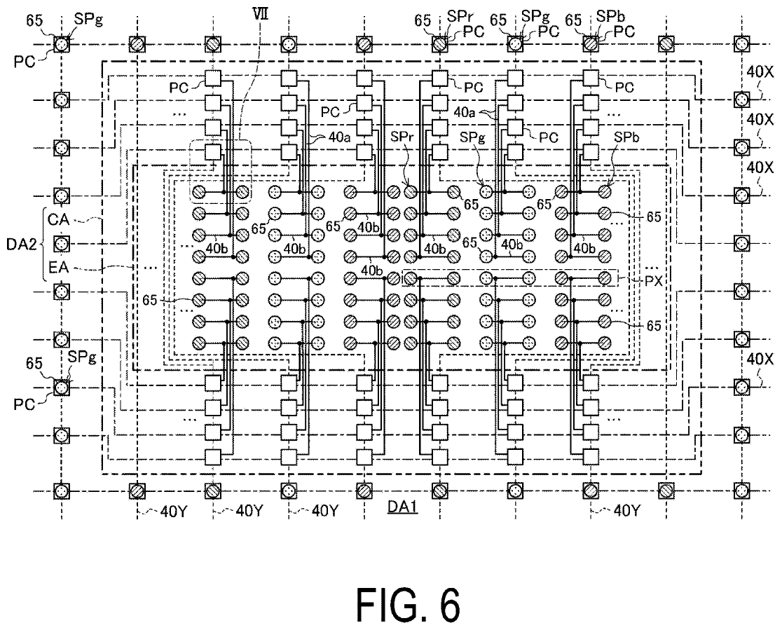

The plurality of pixel circuits PC are provided in the display region DA. The pixel circuit PC in this example is provided for each subpixel SP in the first display region DA1 (see FIG. 3), and is provided for each of two subpixels SP that control light emission in common in the second display region DA2 (see FIG. 6). The pixel circuit PC controls the light emission of the organic EL elements 65 on the basis of signals and voltages supplied by the various wiring lines 40.

The pixel circuit PC includes a plurality of TFTs 45 and a capacitor 46. As illustrated in FIG. 4, each of the plurality of TFTs 45 is configured as a top-gate type. Each of the TFTs 45 includes a semiconductor layer 22, a gate insulating film 23, a gate electrode 25, an interlayer insulating film 30, a first terminal electrode 31, and a second terminal electrode 33.

The semiconductor layer 22 is provided in an island shape on the base coat film 21. The semiconductor layer 22 is individually separated for each TFT 45. The semiconductor layer 22 may be provided in a continuous manner for the plurality of TFTs 45. The semiconductor layer 22 includes a channel region and a pair of conductor regions. The channel region is provided between the pair of conductor regions. The pair of conductor regions are spaced apart from each other with the channel region interposed therebetween.

The semiconductor layer 22 is formed of, for example, low-temperature polycrystalline silicon (LTPS). The semiconductor layer 22 may be formed of an oxide semiconductor. An example of an oxide semiconductor is an indium gallium zinc oxide (In-Ga-Zn-O)-based semiconductor.

The gate insulating film 23 is provided to cover the plurality of semiconductor layers 22. The gate insulating film 23 is formed continuously on the base coat film 21. The gate insulating film 23 is provided in an island shape on each semiconductor layer 22, and may be individually separated for each TFT 45. The gate electrode 25 is provided on the gate insulating film 23. The gate electrode 25 overlaps the channel region of the semiconductor layer 22 via the gate insulating film 23.

The interlayer insulating film 30 is configured by layering a first interlayer insulating film 27 and a second interlayer insulating film 29 in this order on the gate insulating film 23. The second interlayer insulating film 29 is an example of a base insulating film. The interlayer insulating film 30 is provided to cover the plurality of gate electrodes 25. A pair of second contact holes Hb are formed in the gate insulating film 23 and the interlayer insulating film 30 for each TFT 45. The pair of second contact holes Hb penetrate different conductor regions of the corresponding semiconductor layer 22.

The first terminal electrode 31 and the second terminal electrode 33 are provided on the second interlayer insulating film 29 so as to be spaced apart from each other. The first terminal electrode 31 and the second terminal electrode 33 are connected to the semiconductor layer 22 through different second contact holes Hb. In the semiconductor layer 22, the first terminal electrode 31 is connected to one conductor region, and the second terminal electrode 33 is connected to the other conductor region.

The capacitor 46 includes a first capacitance electrode 35, a second capacitance electrode 36, and a first interlayer insulating film 27. The first capacitance electrode 35 is provided on the gate insulating film 23. The second capacitance electrode 36 is provided on the first interlayer insulating film 27. The first capacitance electrode 35 and the second capacitance electrode 36 overlap each other via the first interlayer insulating film 27.

The base coat film 21, the gate insulating film 23, the first interlayer insulating film 27, and the second interlayer insulating film 29 are made of an inorganic insulating material such as silicon oxide, silicon nitride, or silicon oxynitride. The base coat film 21, the gate insulating film 23, the first interlayer insulating film 27, and the second interlayer insulating film 29 may each be composed of a single-layer film or a layered film.

The above-described various wiring lines and electrodes are each made of a metal material such as aluminum (Al), tungsten (W), molybdenum (Mo), tantalum (Ta), chromium (Cr), titanium (Ti), or copper (Cu). The various wiring lines and electrodes may each be composed of a single-layer film or a layered film.

As illustrated in FIGS. 4, 8, and 9, the TFT layer 20 further includes a flattening film 50 and a plurality of connection wiring lines 40r. The flattening film 50 in this example is configured by layering a first flattening film 51, a second flattening film 52, and a third flattening film 53. Each of the first flattening film 51, the second flattening film 52, and the third flattening film 53 is an example of an organic insulating film.

The first flattening film 51 is provided on the second interlayer insulating film 29 so as to cover the plurality of TFTs 45 and the plurality of capacitors 46. The second flattening film 52 and the third flattening film 53 are layered in this order on the first flattening film 51. The first flattening film 51, the second flattening film 52 and the third flattening film 53 extend across the entire display region DA.

The first flattening film 51, the second flattening film 52 and the third flattening film 53 are each made of a photosensitive resin and have light transmittance. Examples of the photosensitive resin include organic resin materials such as a polyimide resin and an acrylic resin, or polysiloxane-based SOG (Spin On Glass) materials. The surface of the TFT layer 20 is flattened by the flattening film 50.

The plurality of connection wiring lines 40r are provided in the display region DA. The connection wiring lines 40r are wiring lines that connect a predetermined TFT 45 (third TFT 45C) among the plurality of TFTs 45 that constitute the pixel circuit PC to the organic EL element 65. The connection wiring lines 40r are provided for each pixel circuit PC. The connection wiring lines 40r include a plurality of first connection wiring lines 40ra and a plurality of second connection wiring lines 40rb.

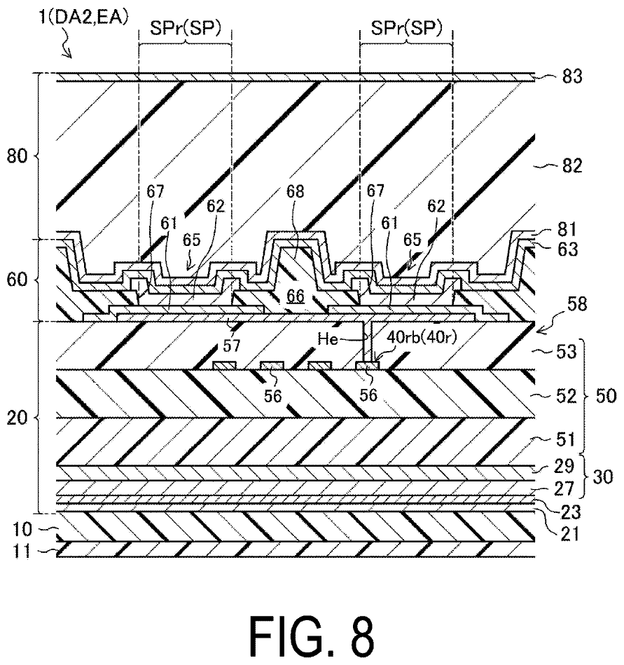

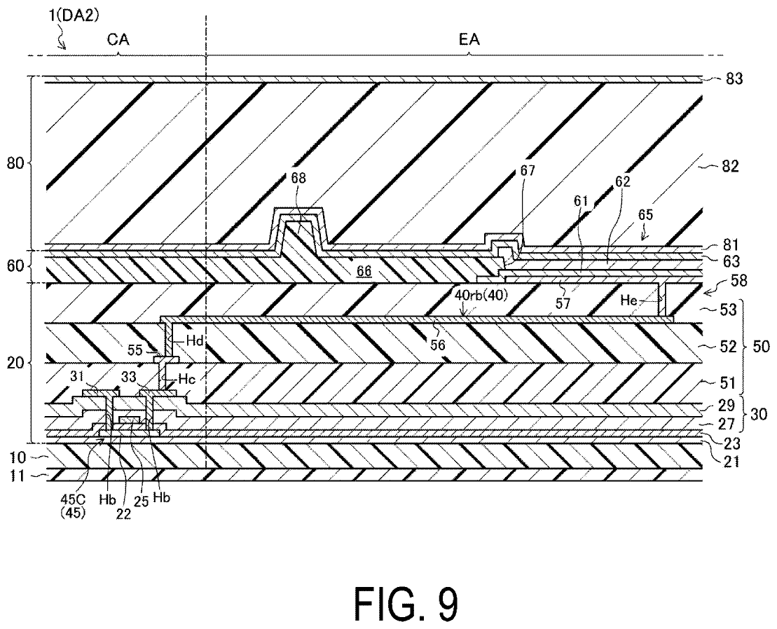

The plurality of first connection wiring lines 40ra are connection wiring lines located in the first display region DA1. Each of the first connection wiring lines 40ra includes a lower layer partial wiring line 55 and an intermediate partial wiring line 56 (see FIG. 4). The plurality of second connection wiring lines 40rb are connection wiring lines located in the second display region DA2. Each second connection wiring line 40rb includes an upper layer partial wiring line 57 in addition to the lower layer partial wiring line 55 and the intermediate partial wiring line 56 (see FIGS. 8 and 9). The lower layer partial wiring line 55, the intermediate partial wiring line 56, and the upper layer partial wiring line 57 are all examples of partial wiring lines, and are formed in different layers with an individual layer (organic insulating film) of the flattening film 50 interposed between adjacent partial wiring lines of them.

The lower layer partial wiring line 55 is a wiring line located in a lower layer among the plurality of partial wiring lines. The lower layer partial wiring line 55 is provided on the first flattening film 51 and located in a layer below the second flattening film 52. The lower layer partial wiring line 55 is a wiring line for connecting a predetermined TFT 45 (third TFT 45C) and the intermediate partial wiring line 56. The lower layer partial wiring line 55 is formed in an island shape, and is connected to a corresponding predetermined TFT 45 (third TFT 45C) via a third contact hole Hc formed in the first flattening film 51.

The intermediate partial wiring line 56 is a wiring line located in an intermediate or upper layer among the plurality of partial wiring lines. The intermediate partial wiring line 56 is provided on the second flattening film 52 and is located in a layer below the third flattening film 53. The intermediate partial wiring line 56 forming the first connection wiring line 40ra is a wiring line for connecting the lower layer partial wiring line 55 and the pixel electrode 61 forming the organic EL element 65. The intermediate partial wiring line 56 forming the second connection wiring line 40rb is a wiring line for connecting the lower layer partial wiring line 55 and the upper layer partial wiring line 57. The intermediate partial wiring line 56 is formed in an island shape and is connected to the corresponding lower layer partial wiring line 55 via a fourth contact hole Hd formed in the second flattening film 52.

The upper layer partial wiring line 57 is a wiring line located in an upper layer among the plurality of partial wiring lines. The upper layer partial wiring line 57 is provided on the third flattening film 53 and is located in a layer below the pixel electrode 61 that constitutes the organic EL element 65. The upper layer partial wiring line 57 is a wiring line for connecting the intermediate partial wiring line 56 and the pixel electrode 61. The upper layer partial wiring line 57 is formed in an island shape and is connected to the corresponding intermediate partial wiring line 56 via a fifth contact hole He formed in the third flattening film 53.

In this manner, the first flattening film 51, the lower layer partial wiring line 55, the second flattening film 52, the intermediate partial wiring line 56, the third flattening film 53, and the upper layer partial wiring line 57 are layered in this order to form a multilayer structure 58. The multilayer structure 58 is a structure in which a plurality of partial wiring lines forming the connection wiring lines 40r and a plurality of organic insulating films are alternately layered.

Similarly to the first frame wiring line 40a and the second frame wiring line 40b, the lower layer partial wiring line 55 is composed of a layered film 75 to be described below. Each of the intermediate partial wiring line 56 and the upper layer partial wiring line 57 is made of a transparent conductive material having light transmittance. The transparent conductive material is, for example, indium tin oxide (ITO). Each of the intermediate partial wiring line 56 and the upper layer partial wiring line 57 may be composed of a single-layer film or a layered film.

### Light-Emitting Element Layer

The light-emitting element layer 60 is provided on the TFT layer 20. As illustrated in FIG. 4, the light-emitting element layer 60 includes a plurality of organic EL elements (organic electroluminescence elements) 65 and an edge cover 66. The organic EL element 65 is an example of a light-emitting element. The organic EL element 65 is configured as a top emission type. In the organic EL element 65, light emitted from the organic EL layer 62 is extracted to the sealing film 80 side.

A plurality of organic EL elements 65 are provided in the display region DA. Specifically, the organic EL element 65 is provided for a corresponding one of a plurality of subpixels SP. Each organic EL element 65 constitutes a subpixel SP. Light emission of each organic EL element 65 is controlled by the operation of the corresponding pixel circuit PC. Each organic EL element 65 includes a pixel electrode 61, an organic EL layer 62, and a common electrode 63.

The pixel electrodes 61 are provided on the third flattening film 53. The pixel electrodes 61 are arranged in a matrix corresponding to each of the plurality of subpixels SP. The pixel electrodes 61 are connected to a predetermined TFT 45 (third TFT 45C) via the connection wiring lines 40r. The pixel electrode 61 functions as an anode, and injects holes into the organic EL layer 62. A conductive material having a large work function is preferably used for the pixel electrode 61.

Examples of the material of the pixel electrode 61 include metals such as silver (Ag), aluminum (Al), nickel (Ni), titanium (Ti), indium (In), and tin (Sn). The material of the pixel electrode 61 may be a metal compound or an alloy. The material of the pixel electrode 61 may be, for example, a conductive oxide such as indium tin oxide (ITO) or indium zinc oxide (IZO). The pixel electrode 61 may be composed of a single-layer film or a layered film.

The edge cover 66 is provided on the third flattening film 53 so as to separate the plurality of pixel electrodes 61. The edge cover 66 is formed in a lattice shape so as to separate the plurality of pixel electrodes 61. The edge cover 66 is located in an upper layer of the pixel electrode 61, covers an outer edge (peripheral end portion) of each pixel electrode 61, and has a plurality of openings 67 that partially expose each pixel electrode 61. The edge cover 66 is made of, for example, a photosensitive resin material similar to that of the first flattening film 51, the second flattening film 52, or the third flattening film 53.

A portion of the surface of the edge cover 66 protrudes towards the sealing film 80 to form a plurality of photo spacers 68. For example, in the manufacture of the organic EL display device 1, the photo spacers 68 play a role of maintaining a distance between a film forming mask used to form a functional layer (for example, a light-emitting layer) that constitutes the organic EL layer 62 and the surface of a target on which the film is to be formed. A plurality of photo spacers 68 are provided in a predetermined array in each of the first display region DA1 and the second display region DA2, and a plurality of photo spacers 68 are also provided in the frame region FA.

The organic EL layer 62 is provided on each pixel electrode 61 within the opening 67 of the edge cover 66. The organic EL layer 62 includes a hole injection layer, a hole transport layer, a light-emitting layer, an electron transport layer, and an electron injection layer. The hole injection layer, the hole transport layer, the light-emitting layer, the electron transport layer, and the electron injection layer are layered in this order on the pixel electrode 61, and are made of known compounds suitable for the respective functions. The organic EL layer 62 emits light when a current is applied between the pixel electrode 61 and the common electrode 63.

The common electrode 63 is continuously provided to be common to the plurality of subpixels SP over the entire display region DA. The common electrode 63 covers the edge cover 66 and each organic EL layer 62, and overlaps each pixel electrode 61 via the organic EL layer 62. The common electrode 63 extends to the frame region FA and is connected to the second frame wiring line 40b. The common electrode 63 functions as a cathode, and injects electrons into the organic EL layer 62. A conductive material having a small work function is preferably used for the common electrode 63.

Examples of the material of the common electrode 63 include conductive oxides such as indium tin oxide (ITO) and indium zinc oxide (IZO). The material of the common electrode 63 may be a metal such as silver (Ag), aluminum (Al), lithium (Li), magnesium (Mg), calcium (Ca), or ytterbium (Yb). The material of the common electrode 63 may be a metal compound or an alloy. The common electrode 63 may be composed of a single-layer film or a layered film.

Sealing Film The sealing film 80 is provided on the light-emitting element layer 60. As illustrated in FIG. 4, the sealing film 80 covers and seals the plurality of organic EL elements 65, and protects each organic EL element 65 (particularly the organic EL layer 62) from moisture, oxygen, and the like. The sealing film 80 is provided over the entire display region DA and extends to the frame region FA. The sealing film 80 includes a first inorganic film 81, an organic film 82, and a second inorganic film 83.

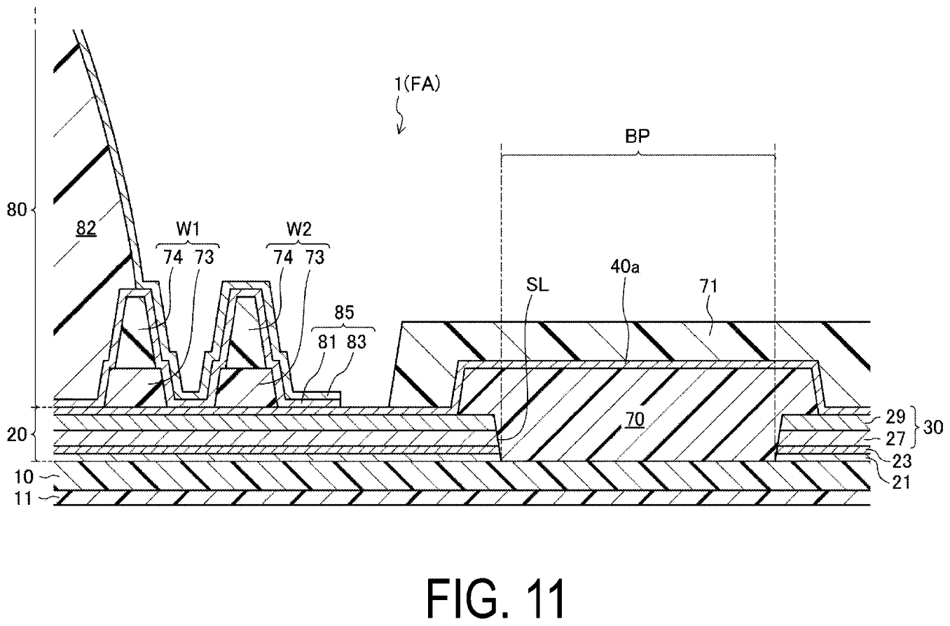

The first inorganic film 81, the organic film 82, and the second inorganic film 83 are provided in this order on the light-emitting element layer 60. The first inorganic film 81 and the second inorganic film 83 extend further toward the outer periphery of the frame region FA than the organic film 82, overlap each other in the outer portion of the frame region FA, and spread to cover the first dam wall W1 and the second dam wall W2 (see FIG. 11). The organic film 82 is provided inside the first dam wall W1 and is enclosed by the first inorganic film 81 and the second inorganic film 83.

The first inorganic film 81 and the second inorganic film 83 are each made of, for example, an inorganic insulating material such as silicon oxide, silicon nitride, or silicon oxynitride. The organic film 82 is made of, for example, an organic resin material such as an acrylic resin, an epoxy resin, a silicone resin, a polyurea resin, a parylene resin, a polyimide resin, or a polyamide resin. The organic film 82 is formed by applying a liquid material (organic insulating material).

### Pixel Circuit

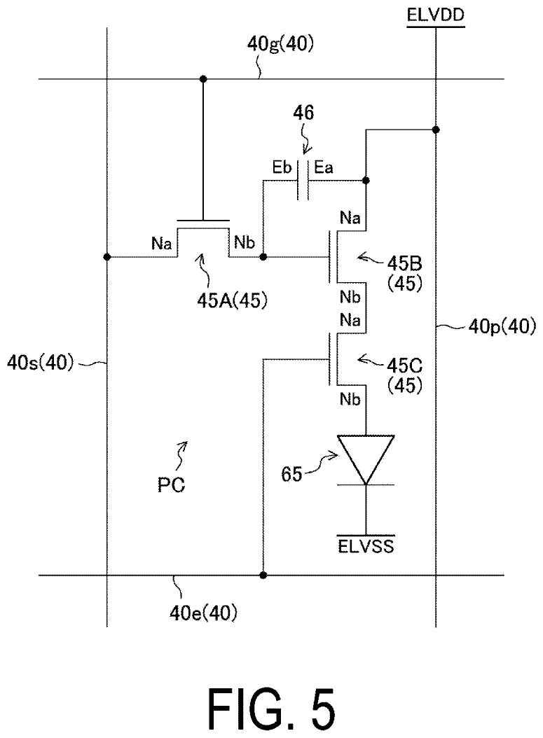

The pixel circuit PC is configured as an equivalent circuit illustrated in FIG. 5. The plurality of TFTs 45 that constitute the pixel circuit PC in this example are a first TFT 45A, a second TFT 45B, and a third TFT 45C. In the equivalent circuit illustrated in FIG. 5, the first and second terminal electrodes 31 and 33 of the TFT 45 are denoted by Na and Nb, respectively, and the first and second capacitance electrodes 47 and 48 of the capacitor 46 are denoted by Ea and Eb, respectively.

The gate electrode 25 of the first TFT 45A is connected to the corresponding gate wiring line 40g. The first terminal electrode 31 of the first TFT 45A is connected to the corresponding source wiring line 40s. The second terminal electrode 33 of the first TFT 45A is connected to the gate electrode 25 of the corresponding second TFT 45B. The first terminal electrode 31 of the second TFT 45B is connected to the corresponding power supply wiring line 40p. The second terminal electrode 33 of the second TFT 45B is connected to the first terminal electrode 31 of the corresponding third TFT 45C.

The gate electrode 25 of the third TFT 45C is connected to the corresponding light emission control wiring line 40e. The first terminal electrode 31 of the third TFT 45C is connected to the second terminal electrode 33 of the corresponding second TFT 45B. The second terminal electrode 33 of the third TFT 45C is connected to the corresponding organic EL element 65 (pixel electrode 61). The first capacitance electrode 47 of the capacitor 46 is connected to the power supply wiring line 40p. The second capacitance electrode 48 of the capacitor 46 is connected to the second terminal electrode 33 of the first TFT 45A and the gate electrode 25 of the second TFT 45B.

### Arrangement Configuration of Organic EL Elements and Pixel Circuits

As illustrated in FIG. 6, in the second display region DA2, an arrangement relationship between the organic EL elements 65 and the pixel circuits PC is different from that in the first display region DA1, and various wiring lines extend irregularly. FIG. 6 schematically illustrates an arrangement relationship between the organic EL elements 65 and the pixel circuits PC in the second display region DA2 and in the first display region DA1 around the second display region DA2.

In the schematic diagram illustrated in FIG. 6, for convenience, the organic EL element 65 is indicated by a circular symbol, and the pixel circuit PC is indicated by a rectangular symbol. In the schematic diagram of FIG. 6, the organic EL elements 65 that emit red light are hatched with leftward inclined lines, the organic EL elements 65 that emit green light are hatched with dots, and the organic EL elements 65 that emit blue light are hatched with rightward inclined lines.

In the schematic diagram of FIG. 6, for convenience, the gate wiring line 40g and the light emission control wiring line 40e are illustrated by alternating dotted-dashed lines as a single representative wiring line (first metal wiring line 40X). The gate wiring line 40g and the light emission control wiring line 40e each extend in the same shape as the first metal wiring line 40X. In the schematic diagram of FIG. 6, for convenience, the source wiring line 40s and the power supply wiring line 40p are indicated by dashed lines as a single representative wiring line (second metal wiring line 40Y). The source wiring line 40s and the power supply wiring line 40p each extend in the same shape as the second metal wiring line 40Y.

As illustrated in FIG. 6, the first metal wiring lines 40X corresponding to the plurality of subpixels SP in the second display region DA2 extend via the outer side of a group of the organic EL elements 65 disposed in a light-emitting element region EA. Each of the first metal wiring lines 40X extends through a circuit arrangement region CA, avoiding the light-emitting element region EA. The second metal wiring lines 40Y corresponding to the plurality of subpixels SP in the second display region DA2 extend via the outer side of the group of the organic EL elements 65 disposed in the light-emitting element region EA.

In the first display region DA1, the pixel circuits PC are disposed at the positions overlapping the corresponding organic EL elements 65 in a plan view and near the periphery thereof. This is illustrated in FIG. 6, where the organic EL element 65 and the pixel circuit PC overlap each other. That is, in the first display region DA1, each of the pixel circuits PC is provided at a position overlapping the subpixel SP formed by the corresponding organic EL element 65.

In the first display region DA1, the lower layer partial wiring line 55 and the intermediate partial wiring line 56 that constitutes each of the first connection wiring lines 40 ra are located in a region overlapping the corresponding pixel electrode 61 in a plan view or on the periphery thereof. Thereby, each of the first connection wiring lines 40ra is pulled out from the TFT 45 onto the second flattening film 52 in a local range. Each pixel electrode 61 in the first display region DA1 is connected to the first connection wiring line 40ra (intermediate partial wiring line 56) through the fifth contact hole He formed in the third flattening film 53 (see FIG. 4).

In the second display region DA2, the pixel circuit PC is disposed at a location spaced apart from the corresponding organic EL element 65 so as not to overlap in a plan view. In the second display region DA2, a region in which the organic EL elements 65 that constitutes each subpixel SP are disposed is separated from a region in which a plurality of pixel circuits PC corresponding to the organic EL elements 65 are disposed. The second display region DA2 includes a light-emitting element region EA and a circuit arrangement region CA.

The light-emitting element region EA is provided in a central portion of the second display region DA2. A plurality of organic EL elements 65 are disposed in the light-emitting element region EA. Specifically, a plurality of sets of organic EL elements 65 are provided in the light-emitting element region EA, with two adjacent organic EL elements 65 forming one set. The two organic EL elements 65 in each set are disposed side by side in the first direction Dx. Light beams emitted by these two organic EL elements 65 have the same color.

The circuit arrangement region CA is provided around the light-emitting element region EA. The plurality of pixel circuits PC are provided in the circuit arrangement region CA. Each of these pixel circuits PC controls the light emission of the organic EL element 65 disposed in the light-emitting element region EA. The pixel circuits PC in the circuit arrangement region CA are provided for each set of organic EL elements 65, and control the light emission of the set of two organic EL elements 65 in common.

In the second display region DA2, the second connection wiring line 40rb is provided for each pair of the set of organic EL elements 65 and the pixel circuit PC. Each of the second connection wiring lines 40rb connects the pixel electrodes 61 of the two organic EL elements 65 forming the corresponding set to the pixel circuit PC, strictly speaking, a predetermined TFT 45 (third TFT 45° C.).

As illustrated in FIG. 9, the intermediate partial wiring line 56 that constitutes each of the second connection wiring lines 40rb is connected to the corresponding lower layer partial wiring line 55 in the circuit arrangement region CA. Then, the intermediate partial wiring line 56 is pulled out from the circuit arrangement region CA to the light-emitting element region EA, and is connected to the upper layer partial wiring line 57 in the light-emitting element region EA as illustrated in FIG. 8. Thereby, each of the second connection wiring lines 40rb extends over the circuit arrangement region CA and the light-emitting element region EA, and is pulled out from the TFT 45 onto the third flattening film 53.

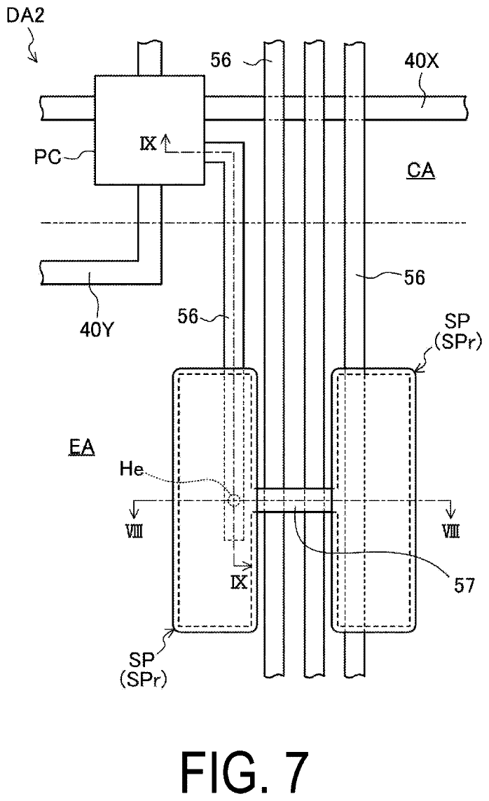

As illustrated in FIG. 7, in the light-emitting element region EA, some of the intermediate partial wiring lines 56 and some of the upper layer partial wiring lines 57 that are not connected to each other extend to intersect each other in a plan view. The third flattening film 53 is interposed at an intersection between the intermediate partial wiring line 56 and the upper layer partial wiring line 57. The pixel electrodes 61 of the two organic EL elements 65 forming a set in the second display region DA2 are provided to overlap a part of the common upper layer partial wiring line 57.

In this manner, in the second display region DA2, the first metal wiring line 40X, the second metal wiring line 40Y, and the second connection wiring line 40rb (the intermediate partial wiring line 56 and the upper layer partial wiring line 57) are designed not to reduce the transmittance of light from the front face side to the back face side in the light-emitting element region EA as much as possible.

### Configuration of Bending Portion

As illustrated in FIG. 11, the base coat film 21, the gate insulating film 23, and the interlayer insulating film 30 (the first interlayer insulating film 27 and the second interlayer insulating film 29) that constitutes the TFT layer 20 are provided to also extend in the frame region FA. In the bending portion BP, a slit SL is formed in a layered body composed of the base coat film 21, the gate insulating film 23, and the interlayer insulating film 30 (the first interlayer insulating film 27 and the second interlayer insulating film 29).

The slit SL is formed in a groove shape that penetrates the layered body in the extension direction of the bending portion BP so as to expose the substrate layer 10. In the slit SL, the base coat film 21, the gate insulating film 23, and the interlayer insulating film 30 (the first interlayer insulating film 27 and the second interlayer insulating film 29) are removed. Accordingly, the bending portion BP has higher flexibility than other portions in the frame region FA.

As also illustrated in FIG. 10, the filling layer 70 is provided at the bending portion BP so as to fill the slit SL. In this example, the filling layer 70 is formed in the same layer and made of the same material as the first flattening film 51. Further, in the frame region FA including the bending portion BP, a coating layer 71 is provided to cover the wiring lines (the upper layer pull-out wiring line 42, the first frame wiring line 40a, and the second frame wiring line 40b) extending on the filling layer 70, and protects the wiring lines.

### First Dam Wall and Second Dam Wall

The first dam wall W1 and the second dam wall W2 in this example have the same configuration. As illustrated in FIGS. 10 and 11, the first dam wall W1 and the second dam wall W2 each include a first wall layer 73 and a second wall layer 74. The first wall layer 73 is provided on the second interlayer insulating film 29. The second wall layer 74 is layered on the first wall layer 73.

In this example, the first wall layer 73 is formed in the same layer and made of the same material as the second flattening film 52. In this example, the second wall layer 74 is formed in the same layer and made of the same material as the edge cover 66. The height of the first dam wall W1 and the height of the second dam wall W2 are designed such that a liquid material (organic resin material) forming the organic film 82 is dammed up to the second dam wall W2.

### First Frame Wiring Line and Second Frame Wiring Line

The first frame wiring line 40a and the second frame wiring line 40b are located in a layer below a part of the multilayer structure 58, specifically, in a layer below the second flattening film 52, and are exposed from the flattening film 50 (the second flattening film 52 and the third flattening film 53). The first frame wiring line 40a and the second frame wiring line 40b are provided in a layer below the first dam wall W1 and the second dam wall W2, and extend to overlap the first dam wall W1 and the second dam wall W2 in a plan view.

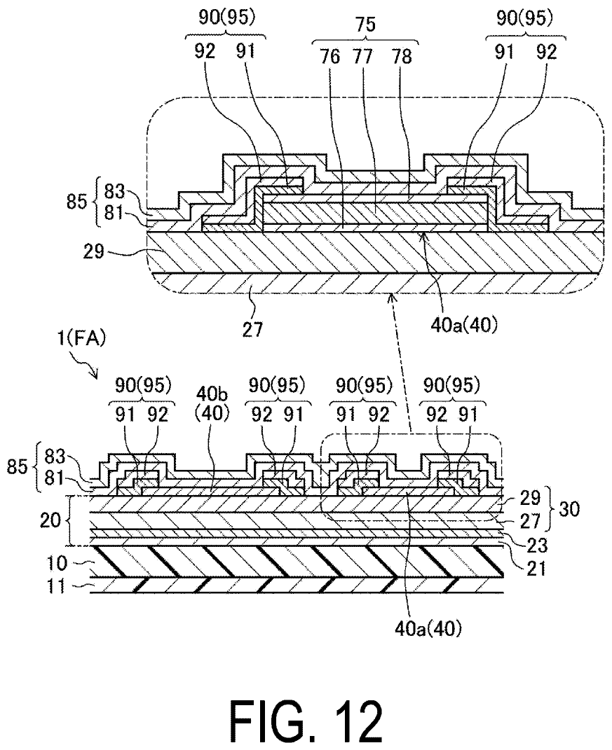

The first frame wiring line 40a and the second frame wiring line 40b in this example are formed in the same layer and made of the same material as the lower layer partial wiring line 55. The first frame wiring line 40a, the second frame wiring line 40b, and the lower layer partial wiring line 55 have the same layered structure. The configurations of the first frame wiring line 40a, the second frame wiring line 40b, and the lower layer partial wiring line 55 are illustrated in FIG. 12 using the first frame wiring line 40a as an example.

As illustrated in FIG. 12, the first frame wiring line 40a, the second frame wiring line 40b, and the lower layer partial wiring line 55 are composed of the layered film 75. The layered film 75 is formed by layering a third metal layer 76, a first metal layer 77, and a second metal layer 78. The third metal layer 76 is formed on the surface of the second interlayer insulating film 29. The first metal layer 77 and the second metal layer 78 are layered in this order on the third metal layer 76.

The conductivity of the first metal layer 77 is higher than the conductivity of the third metal layer 76 and the conductivity of the second metal layer 78. The first metal layer 77 is made of a metal material having good conductivity but having a property of being etched by a developing solution for developing the photosensitive resins of the first flattening film 51, the second flattening film 52, and the third flattening film 53. In addition, the metal material also has a property of being etched by a PAN-based etching solution used for patterning the pixel electrode 61.

Specifically, the first metal layer 77 is made of any one metal of aluminum (Al), silver (Ag), and gold (Au) or an alloy of any of these metals. The first metal layer 77 in this example is made of aluminum (Al) or an aluminum alloy. The thickness of the first metal layer 77 is, for example, approximately 200 nm to 700 nm.

The third metal layer 76 and the second metal layer 78 are each made of a metal material having corrosion resistance to a developing solution for developing the photosensitive resins of the first flattening film 51, the second flattening film 52, and the third flattening film 53. The metal material forming the third metal layer 76 has a property of higher adhesion to the second interlayer insulating film 29 than the first metal layer 77.

Specifically, each of the third metal layer 76 and the second metal layer 78 is made of any one metal of titanium (Ti), molybdenum (Mo), chromium (Cr), and tantalum (Ta), or an alloy of any of these metals. The third metal layer 76 and the second metal layer 78 in this example are each formed of titanium (Ti) or a titanium alloy. The thickness of the third metal layer 76 and the thickness of the second metal layer 78 are, for example, approximately 30 nm to 100 nm.

The first frame wiring line 40a and the second frame wiring line 40b are covered with an inorganic insulating film 85 in the frame region FA. The inorganic insulating film 85 is composed of the first inorganic film 81 and the second inorganic film 83 that constitutes the sealing film 80, and is positioned in a layer above the multilayer structure 58 and further above the light-emitting element layer 60.

Here, when no measures are taken to prevent the first frame wiring line 40a and the second frame wiring line 40b from being exposed to a developing solution or an etching solution used in a process after the formation of the first frame wiring line 40a and the second frame wiring line 40b, the first metal layer 77 is exposed at an end surface in the width direction (hereinafter referred to as a side end surface; the same applies to other wiring lines and constituent layers thereof) until the first inorganic film 81 is formed in the manufacture of the organic EL display device 1. Thus, when the plurality of organic insulating films that constitutes the multilayer structure 58, in this example, the second flattening film 52 and the second flattening film 52 are formed, the first metal layer 77 is repeatedly exposed to the developing solution for patterning the photosensitive resins on the side end surfaces of the first frame wiring line 40a and the second frame wiring line 40b, and is also exposed to the PAN-based etching solution for patterning the pixel electrodes 61.

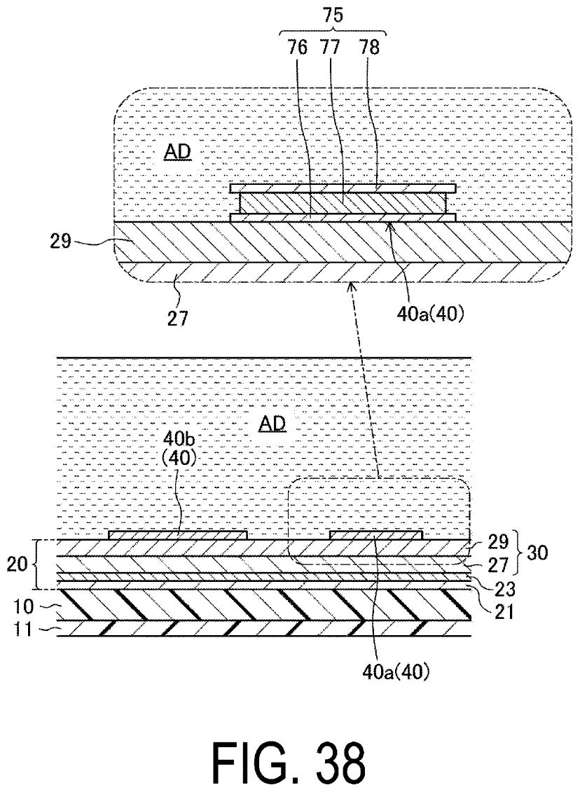

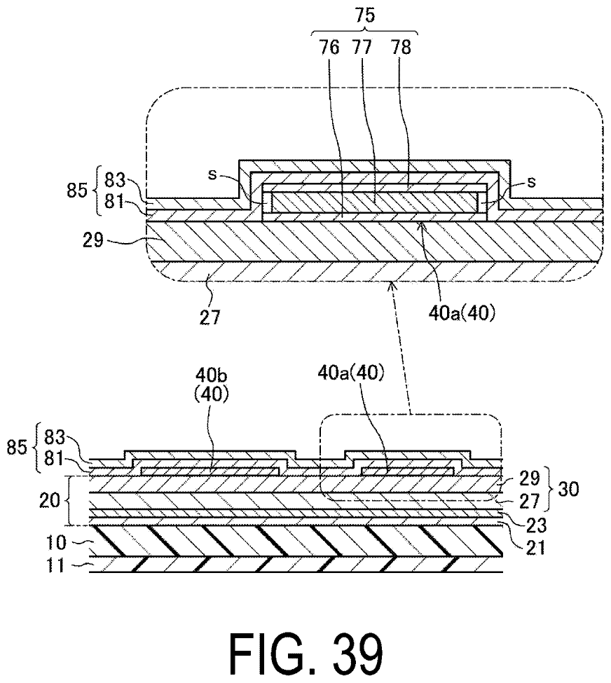

For this reason, as illustrated in FIG. 38, even when the first metal layer 77 is side-etched and recessed to intrude beneath the second metal layer 78 at the side end surfaces of the first frame wiring line 40a and the second frame wiring line 40b, and the first frame wiring line 40a and the second frame wiring line 40b are covered with the inorganic insulating film 85, the side end surfaces of the first frame wiring line 40a and the second frame wiring line 40b cannot be suitably covered with the inorganic insulating film 85, and as illustrated in FIG. 39, a gap s is formed between the first metal layer 77 and the inorganic insulating film 85. The gap s may serve as a path through which moisture enters the display region DA from the outside.

Consequently, as illustrated in FIG. 12, in this embodiment, a protection film 90 is provided in a layer below the inorganic insulating film 85 so as to cover both side end surfaces of the first frame wiring line 40a and both side end surfaces of the second frame wiring line 40b. The protection film 90 protects the first metal layer 77 from the developing solution and the etching solution. As illustrated in FIG. 10, the protection film 90 in this example is provided for each of the first frame wiring line 40a and the second frame wiring line 40b. The protection film 90 is provided in a region that does not overlap the first dam wall W1 and the second dam wall W2 in a plan view.

The protection film 90 provided for the first frame wiring line 40a is provided only in the region overlapping the first frame wiring line 40a and on the periphery of the first frame wiring line 40a in a plan view. A pair of protection films 90 are provided separately at both end portions in the width direction of the first frame wiring line 40a, and the protection films 90 expose the central portion in the width direction of the first frame wiring line 40a. Each of the pair of protection films 90 is formed to cover a range from the surface of the second interlayer insulating film 29 to the side end surface of the first frame wiring line 40a and to extend over the upper surface of the side end portion of the first frame wiring line 40a.

The protection film 90 provided for the second frame wiring line 40b is provided only in the region overlapping the second frame wiring line 40b and on the periphery of the second frame wiring line 40b in a plan view. A pair of the protection films 90 are provided separately at both end portions of the second frame wiring line 40b in the width direction, and the protection films 90 expose the central portion of the second frame wiring line 40b in the width direction. Each of the pair of protection films 90 is formed to cover a range from the surface of the second interlayer insulating film 29 to the side end surface of the second frame wiring line 40b and to extend over the upper surface of the side end portion of the second frame wiring line 40b.

The protection film 90 is formed in the same layer and formed of the same material as the partial wiring line of at least one layer of the lower layer partial wiring line 55, the intermediate partial wiring line 56, and the upper layer partial wiring line 57. The protection film 90 in this example is composed of a layered film 95. The layered film 95 is formed by layering a first protection layer 91 and a second protection layer 92 in this order. The first protection layer 91 is an example of a first conductive layer, and is formed in the same layer and formed of the same material as the intermediate partial wiring line 56. The second protection layer 92 is an example of a first conductive layer, and is formed in the same layer and formed of the same material as the upper layer partial wiring line 57.

The thickness of the first protection layer 91 and the thickness of the second protection layer 92 are, for example, approximately 30 nm to 60 nm. A total thickness of the protection film 90 is, for example, approximately 60 nm to 120 nm. The second protection layer 92 may be formed only on the first protection layer 91, or may be formed to cover the first protection layer 91 and extend to the outer peripheral side of the first protection layer 91. The first inorganic film 81 and the second inorganic film 83 cover the first frame wiring line 40a and the second frame wiring line 40b together with the protection film 90.

### Operation of Organic EL Display Device

In the organic EL display device 1, in each subpixel SP, first, the corresponding light emission control wiring line 40e is selected, and an emission signal indicating an inactive state is input to the third TFT 45C via the light emission control wiring line 40e. Accordingly, the third TFT 45C is set to be in an off state, and the organic EL element 65 is set to be in a non-emitting state.

Then, the gate wiring line 40g corresponding to the non-emitting organic EL element 65 is selected, and a gate signal indicating an active state is input to the first TFT 45A via the gate wiring line 40g. Accordingly, the first TFT 45A is set to be in an on state. When the first TFT 45A is set to be in an on state, a predetermined voltage corresponding to a source signal transmitted via the source wiring line 40s is applied to the second TFT 45B and written to the capacitor 46.

Thereafter, the corresponding light emission control wiring line 40e is selected, and an emission signal indicating an active state is input to the third TFT 45C. Accordingly, the third TFT 45C is set to be in an on state. When the third TFT 45C is set to be in an on state, a drive current corresponding to the voltage applied to the gate electrode of the second TFT 45B is supplied from the power supply wiring line 40p to the organic EL element 65.

In this manner, in the organic EL display device 1, the organic EL element 65 (light-emitting layer) in each subpixel SP emits light with a luminance corresponding to the drive current, thereby displaying an image. Even when the first TFT 45A is set to be in an off state, the light emission of the organic EL element 65 is maintained for each subpixel SP until a gate signal for the next frame is input, because the voltage applied to the gate electrode of the second TFT 45B is held by the capacitor 46.

In the organic EL display device 1, external light is transmitted from the front face side to the back face side in the second display region DA2. When a user performs an operation of executing imaging, the camera 3 receives external light transmitted through the second display region DA2 and converts the external light into an electric signal by an image sensor. Accordingly, in the organic EL display device 1, an image is captured by the camera 3 with the front side of the screen as a target (subject side).

### Method of Manufacturing Organic EL Display Device

In order to manufacture the organic EL display device 1, first, the substrate layer 10 is formed by applying an organic resin material onto the surface of a glass substrate 200 and performing baking treatment. Subsequently, the TFT layer 20, the light-emitting element layer 60, and the sealing film 80 are formed in this order on the substrate layer 10 using a known film formation method such as a chemical vapor deposition (CVD) method, sputtering, or a vacuum vapor deposition method, a known coating method such as a spin coating method or an ink-jet method, and a known patterning technique such as photolithography.

Then, the glass substrate 200 is peeled off from the substrate layer 10 by irradiating the rear surface of the substrate layer 10 with a laser beam from the glass substrate 200 side. Then, a polarizing plate or a cover panel is bonded to the surface of the sealing film 80. Further, the protection film 11 is bonded to the back face of the substrate layer 10. Furthermore, a display control circuit is mounted by connecting the wiring board CB to the terminal portion TP. Thereafter, the organic EL display device 1 is accommodated in the housing together with the camera 3, and the camera 3 is installed in a position overlapping the second display region DA2 in a plan view on the back face side of the organic EL display device 1.

The organic EL display device 1 can be manufactured in the manner described above.

### Process of Forming TFT Layer

In a process of forming the TFT layer 20, first, a plurality of TFTs 45, the capacitor 46, and the like are formed on the substrate layer 10 on the surface of the glass substrate 200. In this stage, in the frame region FA, the slit SL is formed in the layered body including the base coat film 21, the gate insulating film 23, and the interlayer insulating film 30, and a first contact hole Ha is formed in the interlayer insulating film 30.

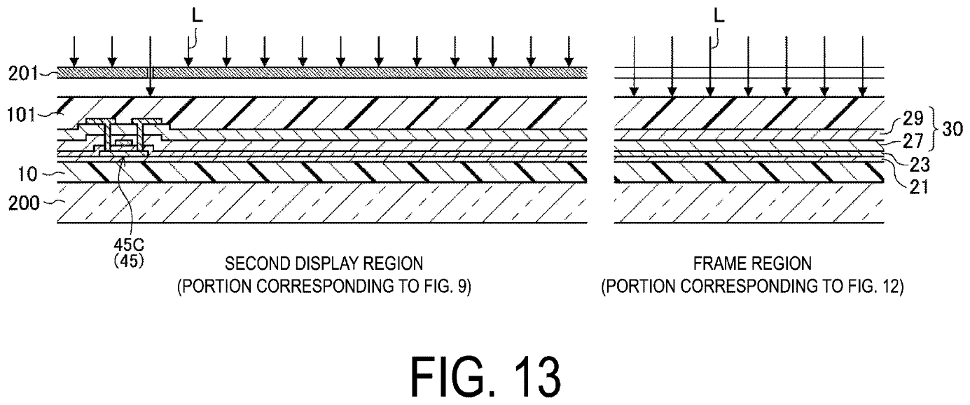

Next, an acrylic photosensitive resin is applied by a known coating method such as a spin coating method or a slit coating method to form a coating film 101 of a photosensitive resin (see FIG. 13). In this example, a positive photosensitive resin is used. Then, the coating film 101 of the photosensitive resin is subjected to pre-baking, exposure, development, and post-baking. Thereby, the first flattening film 51 having a third contact hole Hc is formed. Although not illustrated in the drawing, the filling layer 70 is also formed from the coating film 101 of the same photosensitive resin.

At this time, in the exposure process, as illustrated in FIG. 13, the coating film 101 of the photosensitive resin is irradiated with light L through a first photomask 201 to cause the photosensitive resin to react with the light L. The first photomask 201 in this example is configured to allow the light L to pass through an unnecessary portion of the coating film 101 of the photosensitive resin and to block the light L from reaching a portion where the first flattening film 51 and the filling layer 70 are formed.

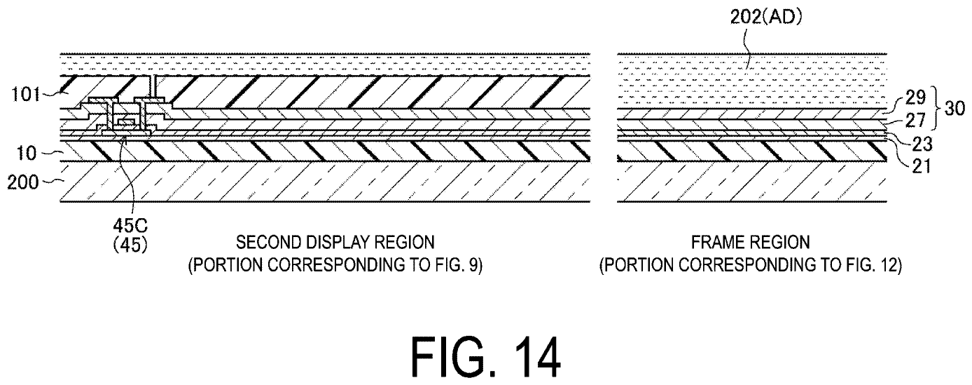

In the developing process, an alkaline developing solution AD is used as a developing solution 202, and the coating film 101 of the photosensitive resin is immersed in the developing solution 202 as illustrated in FIG. 14 to remove unnecessary portions of the coating film 101, specifically, a portion where the third contact hole Hc is formed and a portion where the filling layer 70 is not formed in the frame region FA.

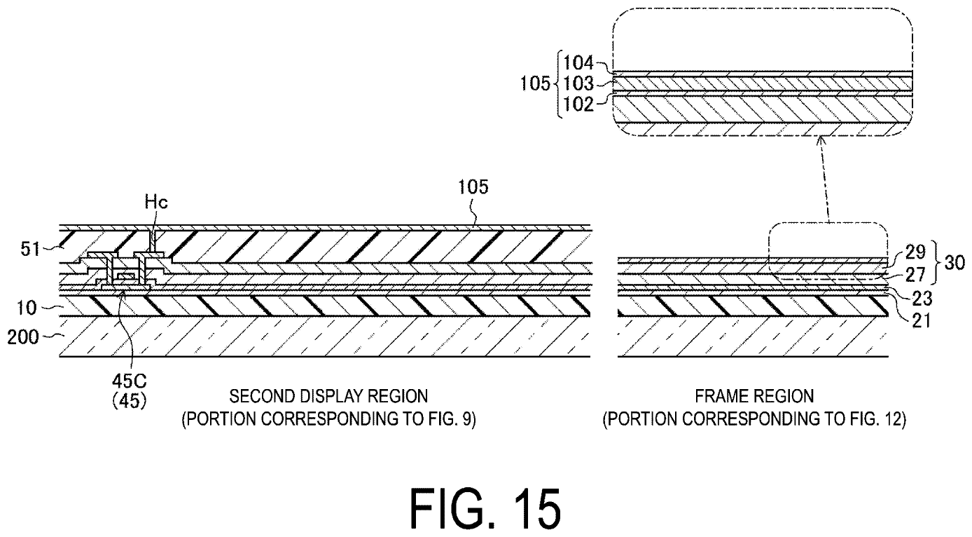

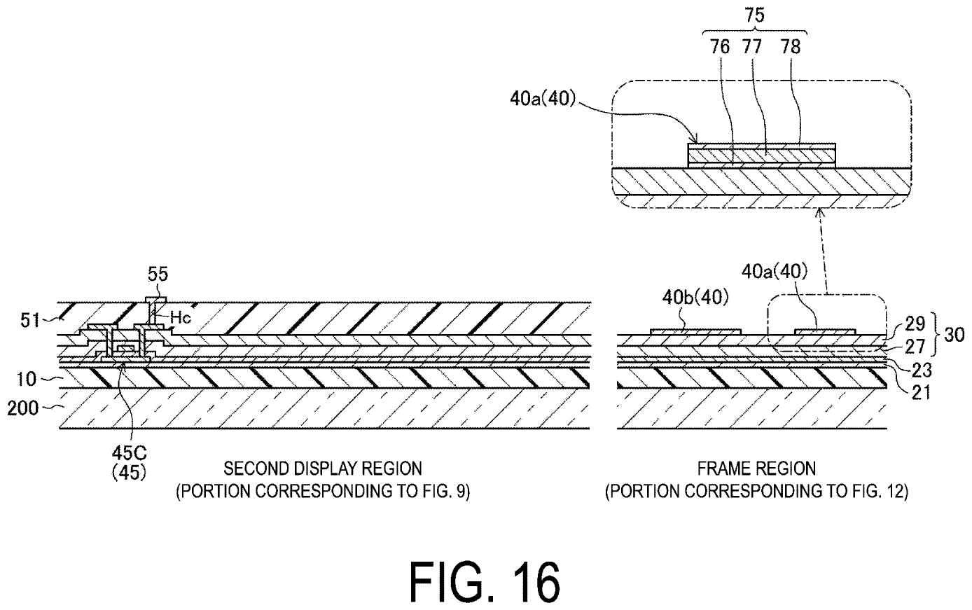

Next, a titanium film (or a titanium alloy film) 102, an aluminum film (or an aluminum alloy film) 103, and a titanium film (or a titanium alloy film) 104 are formed in this order, for example, by a sputtering method on the substrate on which the first flattening film 51 is formed. Thereby, as illustrated in FIG. 15, a metal layered film 105 is formed. Then, the metal layered film 105 is patterned to form the first frame wiring line 40a, the second frame wiring line 40b, and the lower layer partial wiring line 55 as illustrated in FIG. 16.

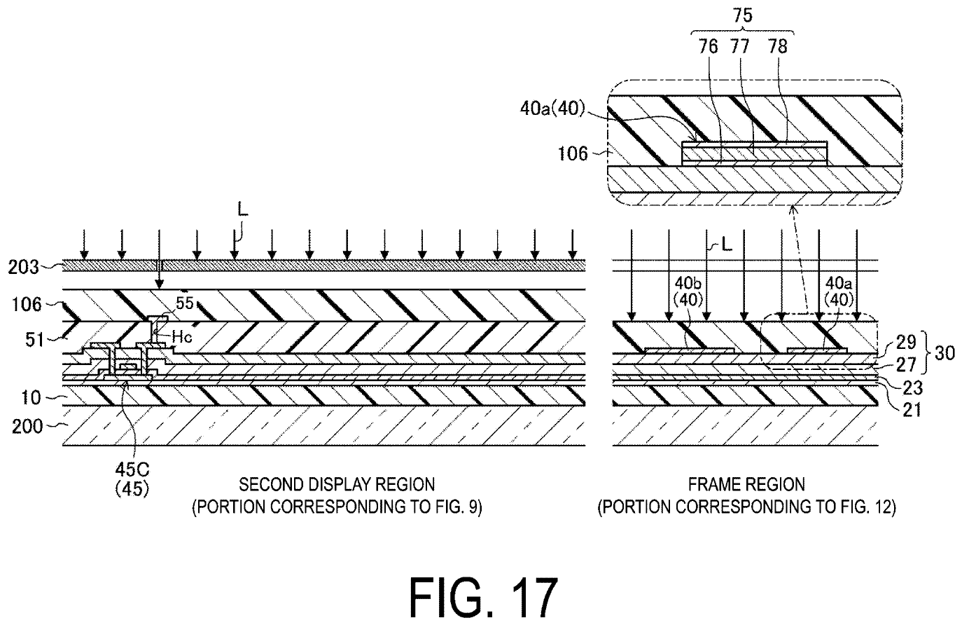

Next, an acrylic photosensitive resin is applied onto the substrate on which the first frame wiring line 40a and the like have been formed, for example, by a known coating method such as a spin coating method or a slit coating method to form a coating film 106 of a photosensitive resin (see FIG. 17). In this example, a positive photosensitive resin is used. Then, the coating film 106 of the photosensitive resin is subjected to pre-baking, exposure, development, and post-baking. Thereby, the second flattening film 52 having a fourth contact hole Hd is formed. Although not illustrated in the drawing, the first wall layer 73 is also formed from the coating film 106 of the same photosensitive resin.

At this time, in the exposure process, as illustrated in FIG. 17, the coating film 106 of the photosensitive resin is irradiated with light L through a second photomask 203 to cause the photosensitive resin to react with the light L. The second photomask 203 in this example is configured to allow the light L to pass through an unnecessary portion of the coating film 106 of the photosensitive resin and to block the light L reaching a portion where the second flattening film 52 is formed and a portion where the first wall layer 73 is formed.

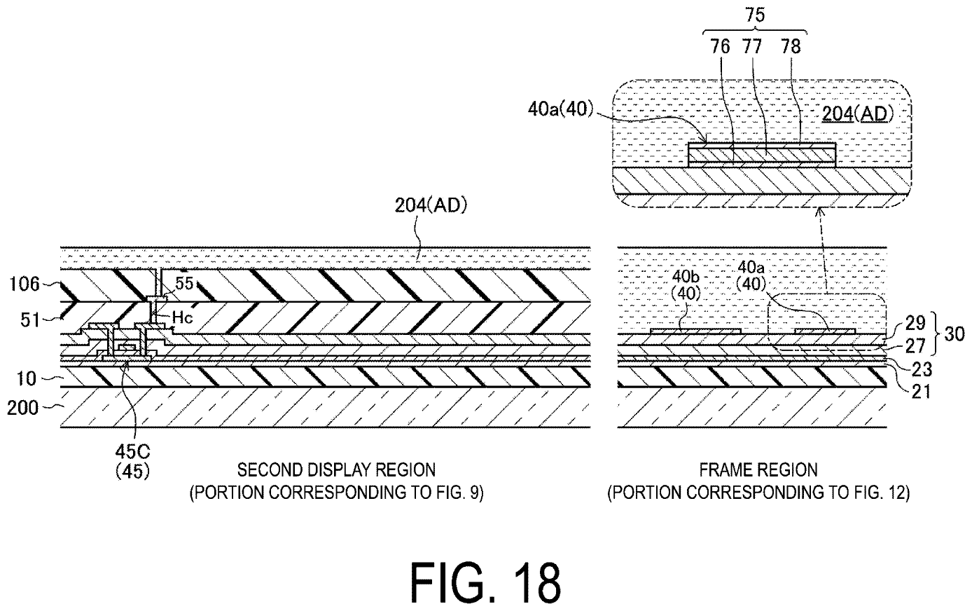

In the developing process, an alkaline developing solution AD is used as a developing solution 204, and the coating film 106 of the photosensitive resin is immersed in the developing solution 204 as illustrated in FIG. 18 to remove unnecessary portions of the coating film 106, specifically, a portion where the fourth contact hole Hd is formed and a portion where the first wall layer 73 is not formed in the frame region FA. Here, the first metal layer 77 of each of the first frame wiring line 40a and the second frame wiring line 40b is exposed to the developing solution 204 at the side end surface of the wiring line. For this reason, each first metal layer 77 is slightly side-etched.

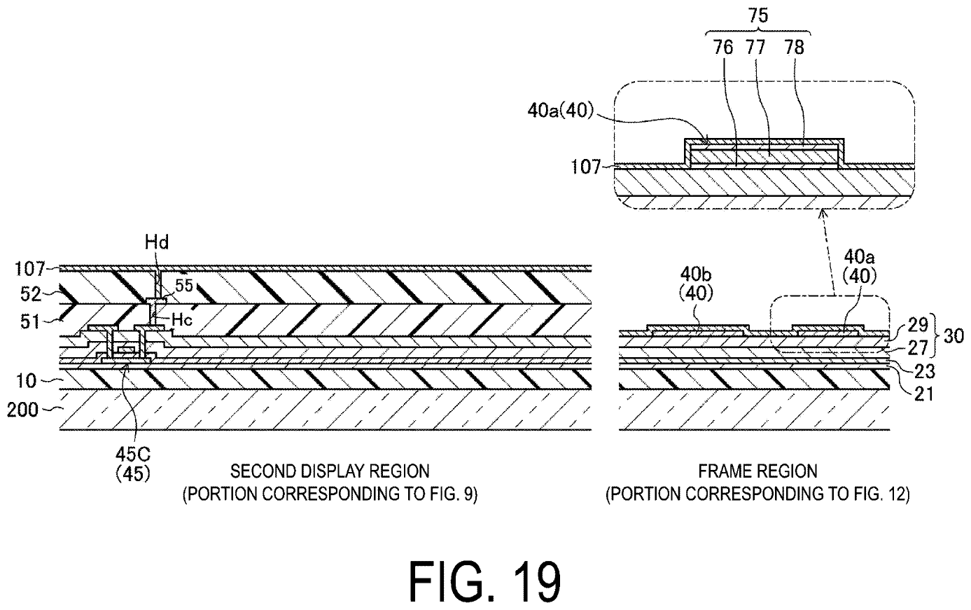

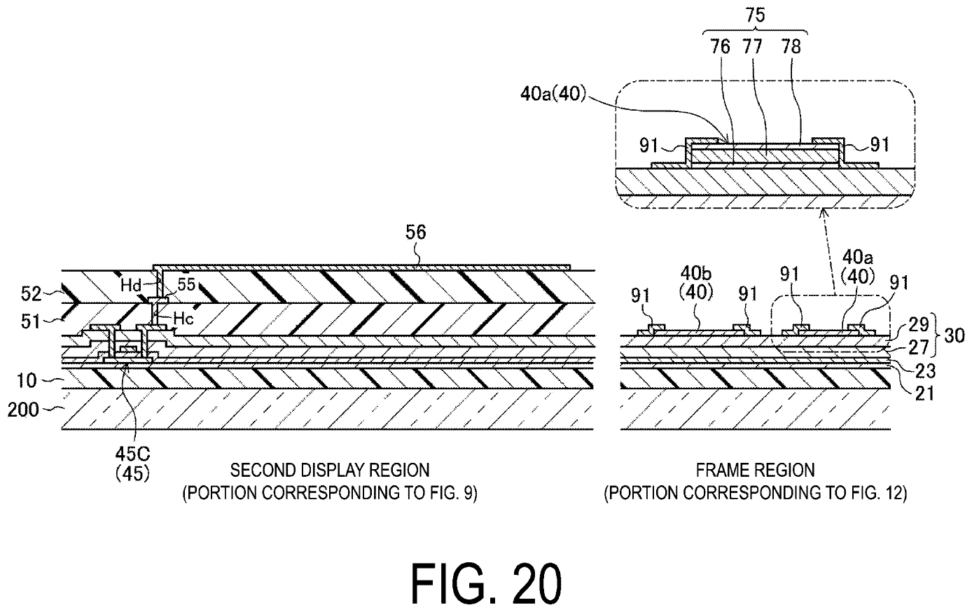

Next, an indium tin oxide film or the like is formed, for example, by a sputtering method on the substrate on which the second flattening film 52 has been formed. Thereby, as illustrated in FIG. 19, the first transparent conductive film 107 is formed so as to cover the first frame wiring line 40a and the second frame wiring line 40b. Then, the first transparent conductive film 107 is patterned to form the intermediate partial wiring line 56 and the first protection layer 91 as illustrated in FIG. 20.

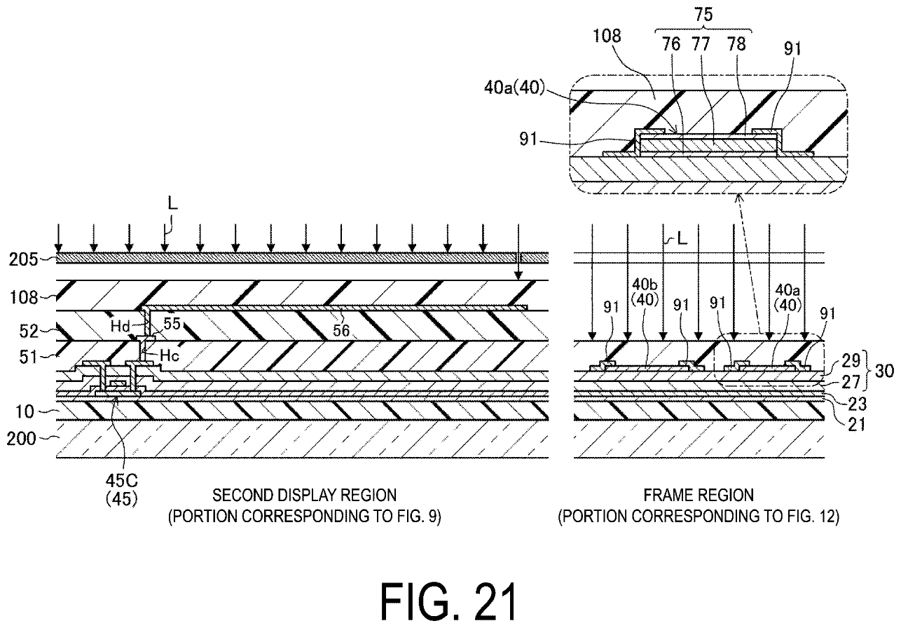

Next, an acrylic photosensitive resin is applied onto the substrate on which the intermediate partial wiring line 56 and the like have been formed, using a known coating method such as a spin coating method or a slit coating method, to form a coating film 108 of a photosensitive resin (see FIG. 21). In this example, a positive photosensitive resin is used. Then, the coating film 108 of the photosensitive resin is subjected to pre-baking, exposure, development, and post-baking. Thereby, the third flattening film 53 having a fifth contact hole He is formed. Although not illustrated in the drawing, the coating layer 71 is also formed from the coating film 108 of the same photosensitive resin.

At this time, in the exposure process, as illustrated in FIG. 21, the coating film 108 of the photosensitive resin is irradiated with light L through a third photomask 205 to cause the photosensitive resin to react with the light L. The third photomask 205 in this example is configured to allow the light L to pass through an unnecessary portion of the coating film 108 of the photosensitive resin and to block the light L reaching a portion where the third flattening film 53 is formed and a portion where the coating layer 71 is formed.

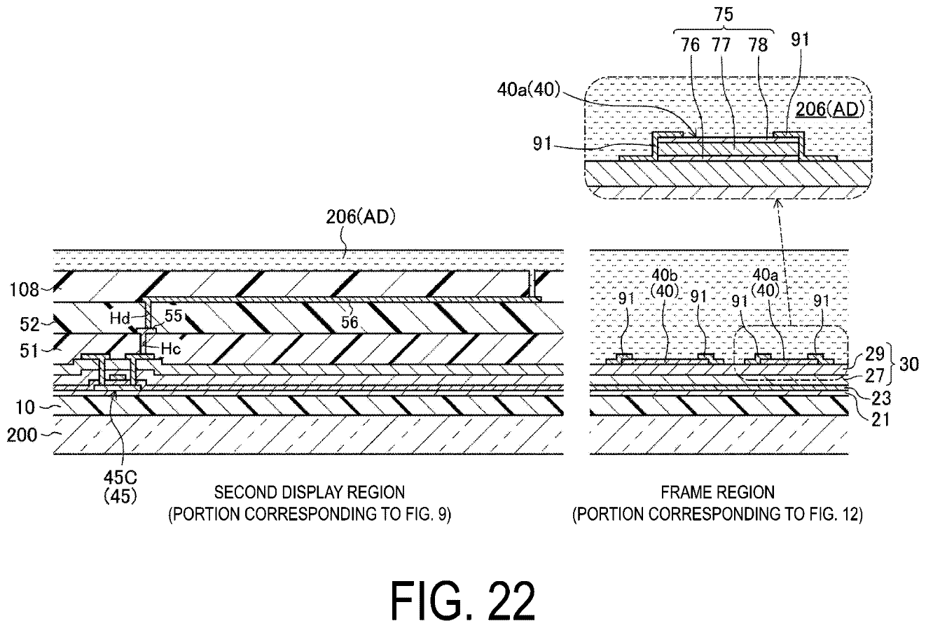

In the developing process, an alkaline developing solution AD is used as a developing solution 206, and the coating film 108 of the photosensitive resin is immersed in the developing solution 206 as illustrated in FIG. 22 to remove unnecessary portions of the coating film 108, specifically, a portion where the fifth contact hole He is formed and a portion where the coating layer 71 is not formed in the frame region FA. Here, both side end surfaces of each of the first frame wiring line 40a and the second frame wiring line 40b are covered with the first protection layer 91. Thus, the first metal layer 77 of each of the first frame wiring line 40a and the second frame wiring line 40b is protected from the developing solution 206 so as not to cause side etching.

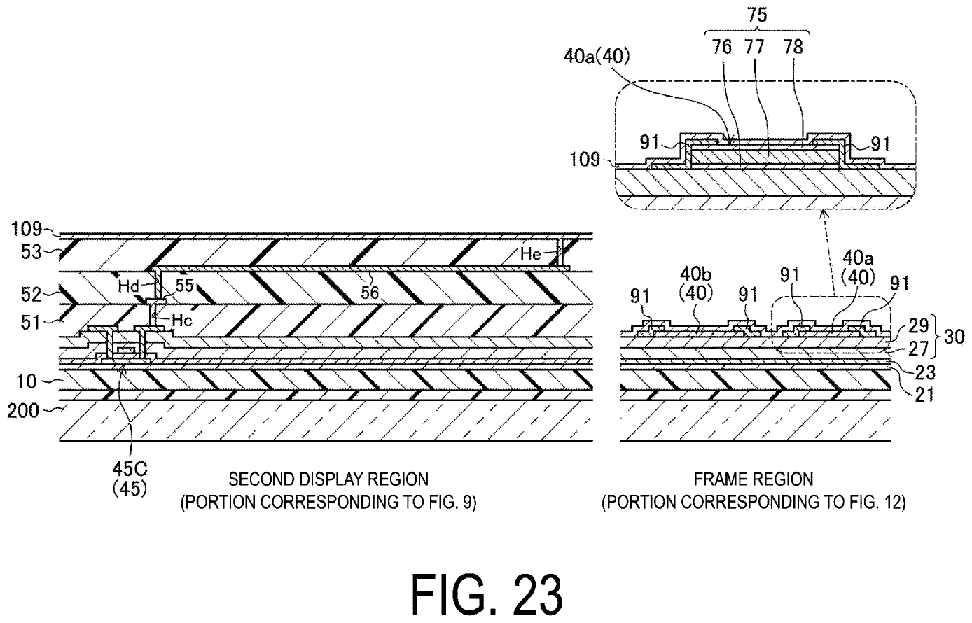

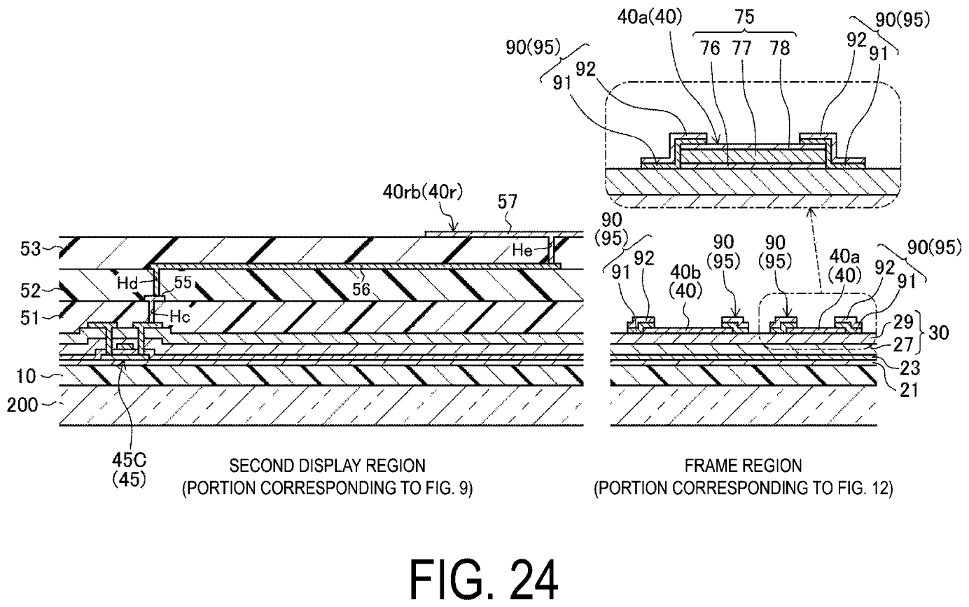

Next, an indium tin oxide film and the like are formed, for example, by a sputtering method on the substrate on which the third flattening film 53 has been formed. Thereby, as illustrated in FIG. 23, a second transparent conductive film 109 is formed to cover the first frame wiring line 40a and the second frame wiring line 40b together with the first protection layer 91. Then, the second transparent conductive film 109 is patterned to form the upper layer partial wiring line 57 and the second protection layer 92 as illustrated in FIG. 24. In this manner, the protection film 90 is formed.

Next, an annealing process is performed on the substrate on which the upper layer partial wiring line 57 and the like are formed at a temperature of approximately 200° C. to 250° C. for approximately 30 to 120 minutes. The intermediate partial wiring line 56 and the upper layer partial wiring line 57 are crystallized by the annealing process. Accordingly, the conductivity and the light transmittance of the intermediate partial wiring line 56 and the upper layer partial wiring line 57 are enhanced. In addition, since the upper layer partial wiring line 57 is crystallized, the upper layer partial wiring line 57 becomes resistant to a PAN-based etching solution used for patterning of the pixel electrode 61 to be performed later.

In this manner, the TFT layer 20 can be formed.

### Process of Forming Light-Emitting Element Layer

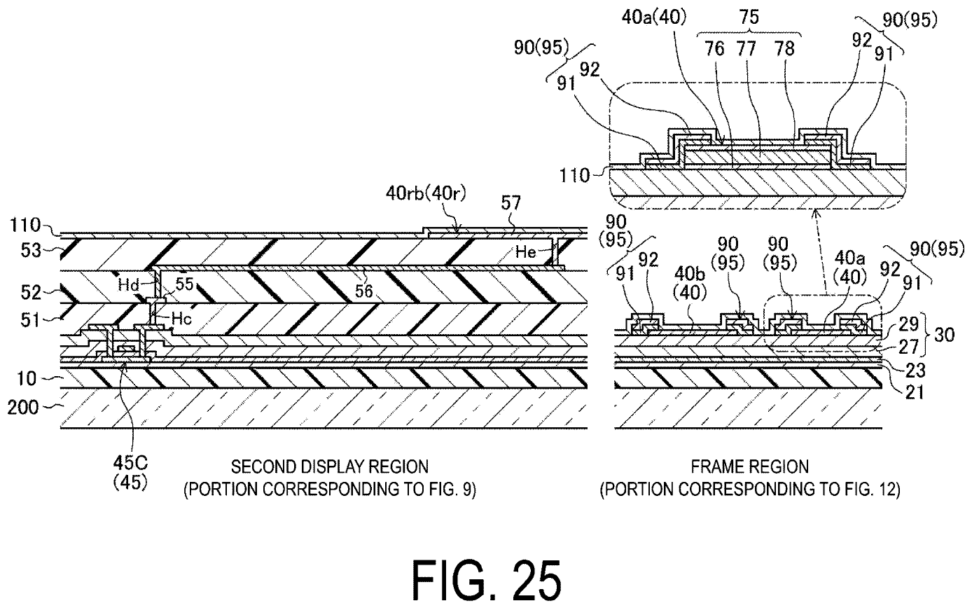

In a process of forming the light-emitting element layer 60, an indium tin oxide film, a silver film, and an indium tin oxide film are formed in this order, for example, by a sputtering method on the substrate on which the upper layer partial wiring line 57 has been formed. Thereby, as illustrated in FIG. 25, a layered conductive film 110 is formed to cover the first frame wiring line 40a and the second frame wiring line 40b together with the protection film 90. Then, the layered conductive film 110 is patterned to form the pixel electrode 61.

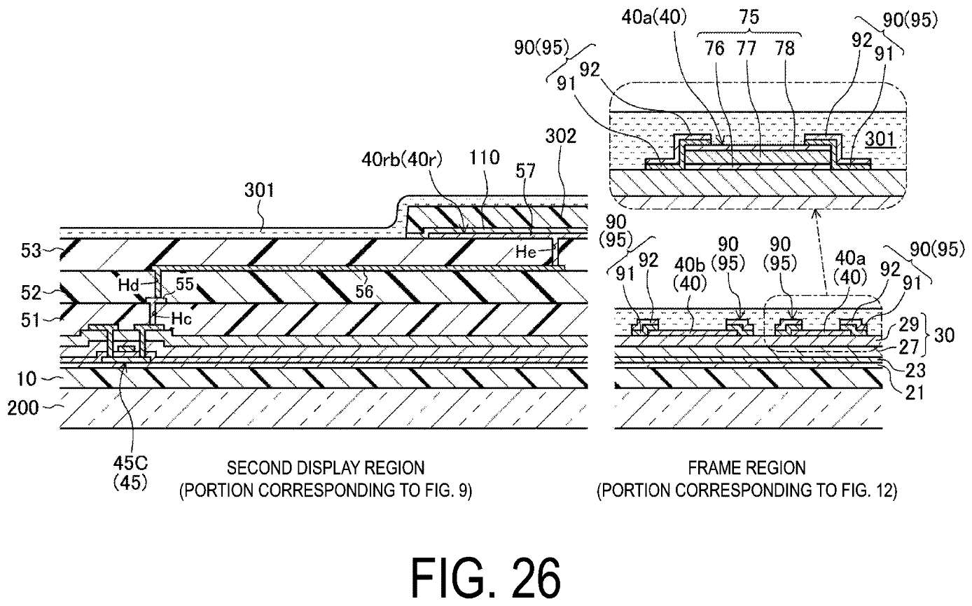

In the patterning of the layered conductive film 110, as illustrated in FIG. 26, a resist 302 is formed at a position where the pixel electrode 61 is to be formed, and wet etching is performed using the resist 302 as a mask. In this wet etching, a PAN-based etching solution in which phosphoric acid, nitric acid, and acetic acid are mixed is used as an etching solution 301. At this time, the upper layer partial wiring lines 57 in the second display region DA2 are exposed to the PAN-based etching solution 301. However, since the upper layer partial wiring line 57 is crystallized in advance and has resistance, the upper layer partial wiring line 57 is not corroded or hardly corroded by the etching solution 301, and can be left in a state of being partially exposed from the pixel electrode 61.

In addition, the layered conductive film 110 covering the first frame wiring line 40a and the second frame wiring line 40b is removed by patterning. Here, both side end surfaces of each of the first frame wiring line 40a and the second frame wiring line 40b are covered with the protection film 90 (the first protection layer 91 and the second protection layer 92). Thus, the first metal layer 77 of each of the first frame wiring line 40a and the second frame wiring line 40b is protected from the PAN-based etching solution 301 so as not to cause side etching.

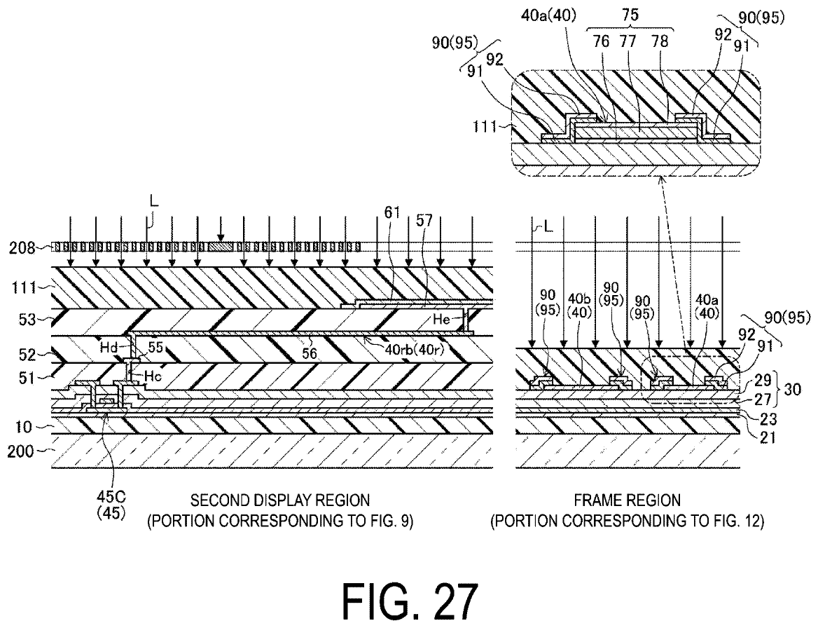

Next, a polyimide-based photosensitive resin is applied onto the substrate on which the pixel electrode 61 is formed, for example, by a known coating method such as a spin coating method or a slit coating method to form a coating film 111 of a photosensitive resin (see FIG. 27). In this example, a positive photosensitive resin is used. Then, the coating film 111 of the photosensitive resin is subjected to pre-baking, exposure, development, and post-baking. Thereby, an edge cover 66 is formed. Although not illustrated in the drawing, the second wall layer 74 is also formed from the coating film 111 of the same photosensitive resin. In this manner, the first dam wall W1 and the second dam wall W2 are constructed.

At this time, in the exposure process, as illustrated in FIG. 27, the coating film 111 of the photosensitive resin is irradiated with light L through a fourth photomask 208 to cause the photosensitive resin to react with the light L. The fourth photomask 208 in this example is a half-tone mask or a gray-tone mask, and is configured to allow the light L to pass through an unnecessary portion in the coating film 111 of the photosensitive resin, to completely block the light L from reaching a portion where the photo spacer 68 is formed and to partially block the light L reaching other portions where the edge cover 66 is formed.

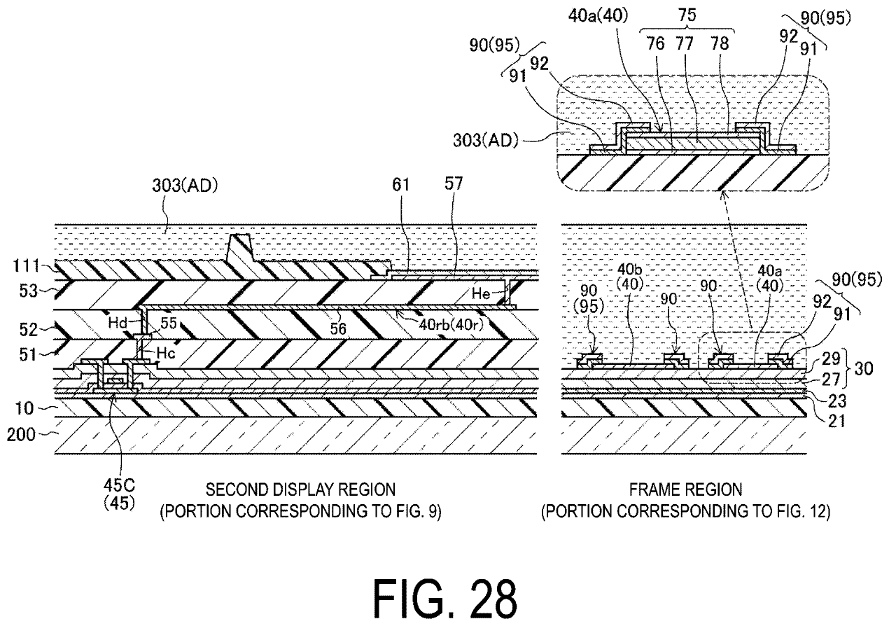

In the developing process, an alkaline developing solution AD is used as a developing solution 303, and the coating film 111 of the photosensitive resin is immersed in the developing solution 303 as illustrated in FIG. 28 to remove unnecessary portions of the coating film 111, specifically, a portion where the opening 67 of the edge cover 66 is formed and a portion where the second wall layer 74 is not formed in the frame region FA. Here, both side end surfaces of each of the first frame wiring line 40a and the second frame wiring line 40b are covered with the protection film 90 (the first protection layer 91 and the second protection layer 92). Thus, the first metal layer 77 of each of the first frame wiring line 40a and the second frame wiring line 40b is protected from the developing solution 303 so as not to cause side etching.

Thereafter, the organic EL layer 62 and the common electrode 63 are sequentially formed on the substrate on which the edge cover 66 and the like are formed by using a known method. In this manner, the light-emitting element layer 60 can be formed.

### Characteristics of First Embodiment

In the organic EL display device 1 according to the first embodiment, the connection wiring lines 40r that connect the organic EL elements 65 and the pixel circuits PC include the lower layer partial wiring lines 55, the intermediate partial wiring lines 56, and the upper layer partial wiring lines 57 that are formed in different layers with the second flattening film 52 and the third flattening film 53 interposed therebetween, and constitute the multilayer structure 58 in which the plurality of partial wiring lines and the plurality of organic insulating films are alternately layered. The second flattening film 52 and the third flattening film 53 are made of a photosensitive resin, and are patterned using an alkaline developing solution. The first frame wiring line 40a and the second frame wiring line 40b are located in a layer below the second flattening film 52 of the multilayer structure 58, but are exposed from the second flattening film 52 and the third flattening film 53. Thus, when the protection film 90 is not provided, the organic EL display device 1 is exposed to the alkaline developing solution AD every time the second flattening film 52 and the third flattening film 53 are formed during the manufacturing process of the organic EL display device 1.

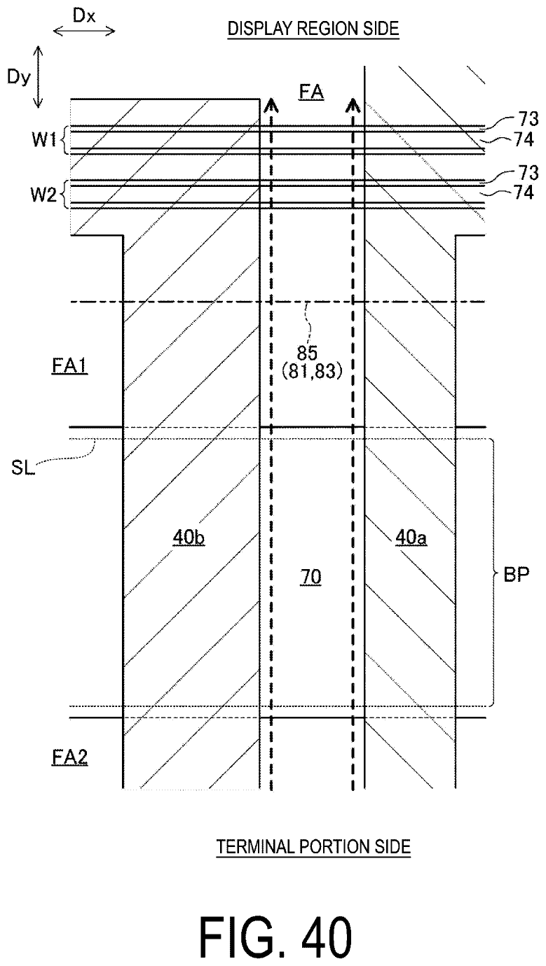

The first frame wiring line 40a and the second frame wiring line 40b are composed of the layered film 75 in which the third metal layer 76, the first metal layer 77, and the second metal layer 78 are layered in this order. The first metal layer 77 is made of any one metal of aluminum (Al), copper (Cu), silver (Ag), and gold (Au) or an alloy of any of these metals, and has a property of being etched by the alkaline developing solution AD. On the other hand, the second metal layer 78 is made of any one metal of titanium (Ti), molybdenum (Mo), chromium (Cr), and tantalum (Ta) or an alloy of any of these metals, and has corrosion resistance to the alkaline developing solution AD. For this reason, as illustrated in FIG. 38, when the side end surfaces of the first frame wiring line 40a and the second frame wiring line 40b are exposed to the alkaline developing solution AD a plurality of times, the first metal layer 77 is side-etched and recessed, and as illustrated in FIG. 39, a gap s is formed between the inorganic insulating film 85 to be formed later and the first metal layer 77 at the side end portions of the first frame wiring line 40a and the second frame wiring line 40b. The gap s can serve as a path through which moisture enters the display region DA from the frame region FA as indicated by a dashed arrow in FIG. 40.

On the other hand, in the organic EL display device 1 according to the first embodiment, both side end surfaces of the first frame wiring line 40a and the second frame wiring line 40b are covered with the protection film 90. Accordingly, the first metal layers 77 of the first frame wiring line 40a and the second frame wiring line 40b are not exposed to the alkaline developing solution AD, and thus it is possible to prevent the first metal layers 77 from being side-etched. Thereby, the first frame wiring line 40a and the second frame wiring line 40b can be suitably covered with the inorganic insulating film 85 together with the protection film 90, and the gaps s formed at the side end portions of the first frame wiring line 40a and the second frame wiring line 40b can be reduced or eliminated. Thus, it is possible to prevent moisture from entering the display region DA along the first frame wiring line 40a and the second frame wiring line 40b. As a result, the reliability of the organic EL display device 1 can be enhanced.

In the organic EL display device 1 according to the first embodiment, the first frame wiring line 40a and the second frame wiring line 40b are formed in the same layer and formed of the same material as the lower layer partial wiring line 55 located in the lower layer in the multilayer structure 58. Accordingly, the first frame wiring line 40a and the second frame wiring line 40b can be formed by patterning from the same film as the lower layer partial wiring line 55 at the same time. In this manner, the manufacturing process of the organic EL display device 1 can be simplified as compared with a case where the first frame wiring line 40a and the second frame wiring line 40b are formed separately and independently of the lower layer partial wiring line 55.

In the organic EL display device 1 according to the first embodiment, the protection film 90 is composed of the layered film 95. The layered film 95 is formed by layering the first protection layer 91 and the second protection layer 92. The first protection layer 91 and the second protection layer 92 are formed in the same layer and formed of the same material as the intermediate partial wiring line 56 and the upper layer partial wiring line 57, respectively. Accordingly, the first protection layer 91 and the second protection layer 92 can be formed by patterning from the same film as the intermediate partial wiring line 56 and the upper layer partial wiring line 57, respectively, at the same time. In this manner, the manufacturing process of the organic EL display device 1 can be simplified as compared with a case where the protection film 90 is formed separately and independently of the intermediate partial wiring line 56 and the upper layer partial wiring line 57.

In the organic EL display device 1 according to the first embodiment, the protection film 90 is provided only in a position overlapping the first frame wiring line 40a and on the periphery of the first frame wiring line 40a in a plan view, and in a position overlapping the second frame wiring line 40b and on the periphery of the second frame wiring line 40b in a plan view. For example, when the protection film 90 is continuously provided over a wide range such as the entire frame region FA, moisture or gas is likely to remain inside the organic EL display device 1 in the manufacturing process of the organic EL display device 1 because moisture or gas between layers and in the layers that constitute the organic EL display device 1 is prevented from escaping. This adversely affects the organic EL element 65 later and reduces the reliability of the organic EL display device 1. On the other hand, when the protection film 90 is locally provided at a necessary position as described above, it is possible to prevent moisture or gas between the layers and in the layers that constitute the organic EL display device 1 from being prevented from escaping as much as possible in the manufacturing process of the organic EL display device 1. Thereby, the reliability of the organic EL display device 1 can be enhanced.

In the organic EL display device 1 according to the first embodiment, the protection film 90 is provided at both end portions of the first frame wiring line 40a in the width direction and at both end portions of the second frame wiring line 40b in the width direction. Thereby, it is possible to prevent the first metal layer 77 from being side-etched on both side end surfaces of each of the first frame wiring line 40a and the second frame wiring line 40b. Thereby, the first frame wiring line 40a and the second frame wiring line 40b can be suitably covered with the inorganic insulating film 85 together with the protection film 90. The central portions of the first frame wiring line 40a and the second frame wiring line 40b in the width direction are exposed from the protection film 90. This is advantageous in that, in the manufacturing process of the organic EL display device 1, moisture and gas between the layers and in the layers that constitute the organic EL display device 1 are not prevented from escaping.

In the organic EL display device 1 according to the first embodiment, the first frame wiring line 40a and the second frame wiring line 40b are each a power supply trunk line for applying a voltage to the organic EL element 65. The conductivity of the first metal layer 77 is higher than the conductivities of the third metal layer 76 and the second metal layer 78. Accordingly, the conductivities of the first frame wiring line 40a and the second frame wiring line 40b can be adjusted by the first metal layer 77. The layered film 75 including the first metal layer 77 is suitably adopted for the power supply trunk line because the power supply trunk line preferably has high conductivity.

In the organic EL display device 1 according to the first embodiment, the protection film 90 is provided in a region that does not overlap the first dam wall W1 and the second dam wall W2 in a plan view. Even when the protection film 90 is not provided over the entire length of the first frame wiring line 40a and the entire length of the second frame wiring line 40b as described above, it is possible to reduce or eliminate the gaps s formed at the end portions of the first frame wiring line 40a and the second frame wiring line 40b in the width direction in the portion where the protection film 90 is provided. This also makes it possible to prevent moisture from flowing along the first frame wiring line 40a and the second frame wiring line 40b and to obtain the effect of preventing moisture from entering the display region DA.

In the organic EL display device 1 according to the first embodiment, each of the intermediate partial wiring line 56 and the upper layer partial wiring line 57 is formed of a transparent conductive material such as indium tin oxide (ITO). This is advantageous for increasing the transmittance of light in the second display region DA2.

In the organic EL display device 1 according to the first embodiment, a plurality of organic EL elements 65 in the second display region DA2 are disposed in the light-emitting element region EA, and a plurality of pixel circuits PC that control the light emission of the organic EL elements 65 in the light-emitting element region EA are disposed around the light-emitting element region EA. This eliminates the need to provide pixel circuits PC in the light-emitting element region EA. Accordingly, light can be suitably transmitted from the front face side to the back face side of the display region DA in the light-emitting element region EA, thereby making it possible to secure external light used by the camera 3. This is advantageous for the camera 3 to function properly. The intermediate partial wiring line 56 and the upper layer partial wiring line 57 provided in different layers intersect each other via the third flattening film 53 in the light-emitting element region EA. Accordingly, it is possible to increase the degree of freedom of the layout of the connection wiring line 40r.

### Second Embodiment

An organic EL display device 1 according to a second embodiment differs from that in the above-described first embodiment in the configuration of the protection film 90. In this embodiment, the organic EL display device 1 is configured in the same manner as that in the above-described first embodiment, except that the configuration of the protection film 90 differs from that in the above-described first embodiment.

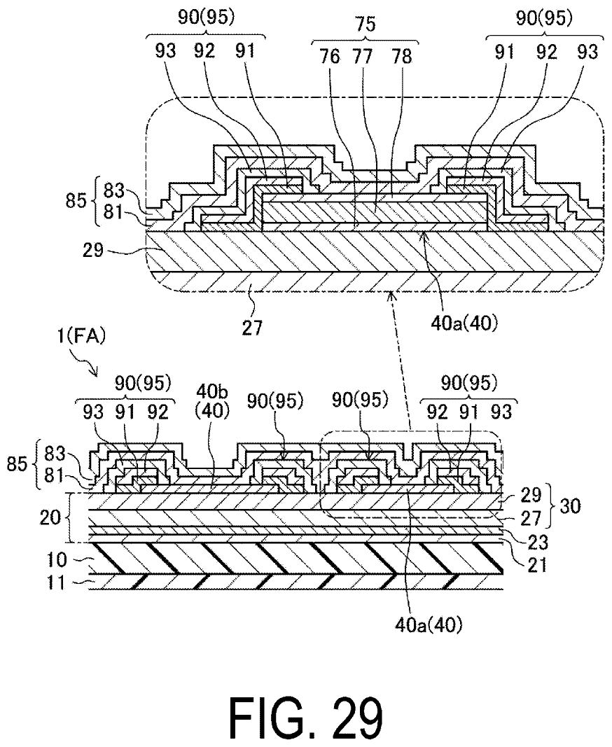

As illustrated in FIG. 29, in the organic EL display device 1 according to the second embodiment, the layered film 95 forming the protection film 90 is configured to include a third protection layer 93 in addition to the first protection layer 91 and the second protection layer 92. The third protection layer 93 is provided to cover the first protection layer 91 and the second protection layer 92 in the pair of protection films 90 in each of the first frame wiring line 40a and the second frame wiring line 40b.

The third protection layer 93 is an example of a second conductive layer, and is formed in the same layer and formed of the same material as the pixel electrode 61. In order to manufacture the organic EL display device 1 according to the second embodiment, when the layered conductive film 110 is patterned to form the pixel electrode 61 in the process of forming the light-emitting element layer 60 described above, the third protection layer 93 may also be formed from the same layered conductive film 110.

### Characteristics of Second Embodiment

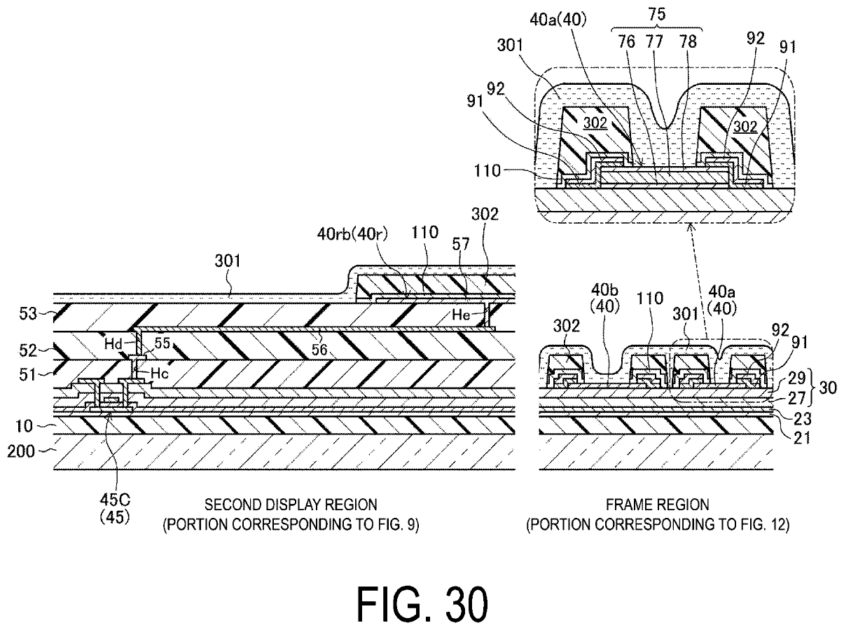

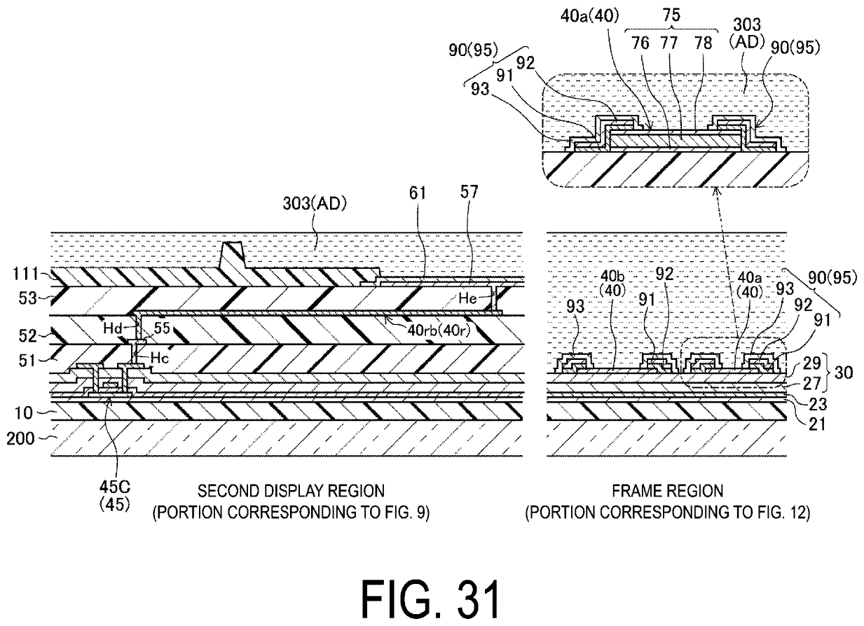

In the organic EL display device 1 according to the second embodiment, the protection film 90 is configured to include the third protection layer 93 formed in the same layer and formed of the same material as the pixel electrode 61. Accordingly, as illustrated in FIG. 30, since the resist 302 is also provided at a position where the third protection layer 93 is to be formed at the time of patterning the pixel electrode 61, the respective first metal layers 77 of the first frame wiring line 40a and the second frame wiring line 40b can be protected from a PAN-based etching solution 301, and as illustrated in FIG. 31, the respective first metal layers 77 can be suitably protected from the alkaline developing solution 303 used for patterning the edge cover 66. The third protection layer 93 may be simultaneously formed from the same film as the pixel electrode 61. In this manner, the manufacturing process of the organic EL display device 1 can be simplified as compared with a case where the third protection layer 93 is formed separately and independently of the pixel electrode 61.

### Third Embodiment

An organic EL display device 1 according to a third embodiment differs from that in the above-described first embodiment in the configuration of the flattening film 50 and the configuration of the protection film 90. In this embodiment, the organic EL display device 1 is configured in the same manner as in the above-described first embodiment, except that the configuration of the flattening film 50 and the configuration of the protection film 90 differ from those in the above-described first embodiment.

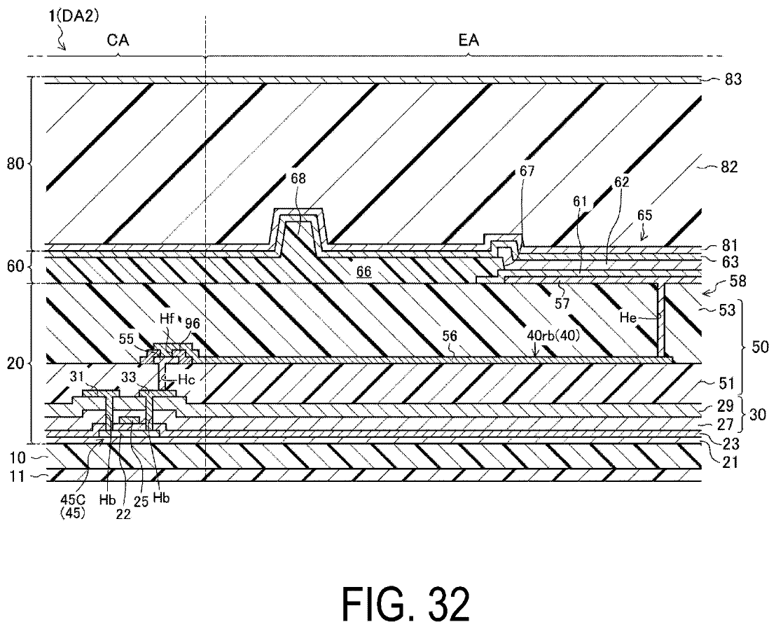

As illustrated in FIG. 32, in the organic EL display device 1 according to the third embodiment, the flattening film 50 is formed by layering the first flattening film 51 and the third flattening film 53. Instead of the second flattening film 52, a passivation film 96 is provided between the first flattening film 51 and the third flattening film 53. The passivation film 96 is an example of an interlayer insulating film.

The lower layer partial wiring line 55 is covered with the passivation film 96. The passivation film 96 is provided only in a region overlapping the lower layer partial wiring line 55 in a plan view and on the periphery of the lower layer partial wiring line 55. The intermediate partial wiring line 56 is connected to the lower layer partial wiring line 55 via a sixth contact hole Hf formed in the passivation film 96.

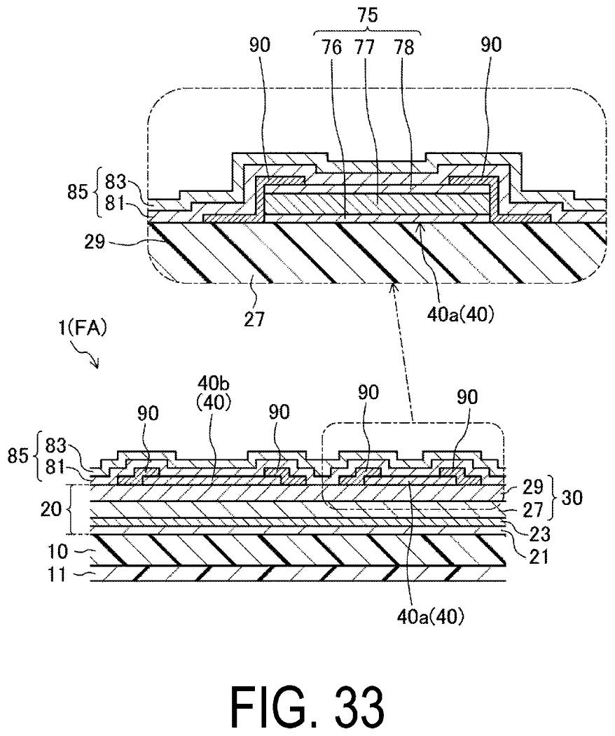

As illustrated in FIG. 33, in the organic EL display device 1 of the third embodiment, the protection film 90 is composed of a single film and is formed of an inorganic insulating material. The protection film 90 is formed in the same layer and formed of the same material as the passivation film 96. Examples of the inorganic insulating material forming the passivation film 96 and the protection film 90 include silicon nitride. The thickness of the passivation film 96 and the thickness of the protection film 90 are, for example, approximately 50 nm to 120 nm.

In order to manufacture the organic EL display device 1 according to the third embodiment, an inorganic insulating film is formed, for example, by a plasma CVD method on the substrate after the lower layer partial wiring line 55 is formed in the process of forming the TFT layer 20 described above. Then, the inorganic insulating film is patterned to form the passivation film 96 and the protection film 90.

### Characteristics of Third Embodiment

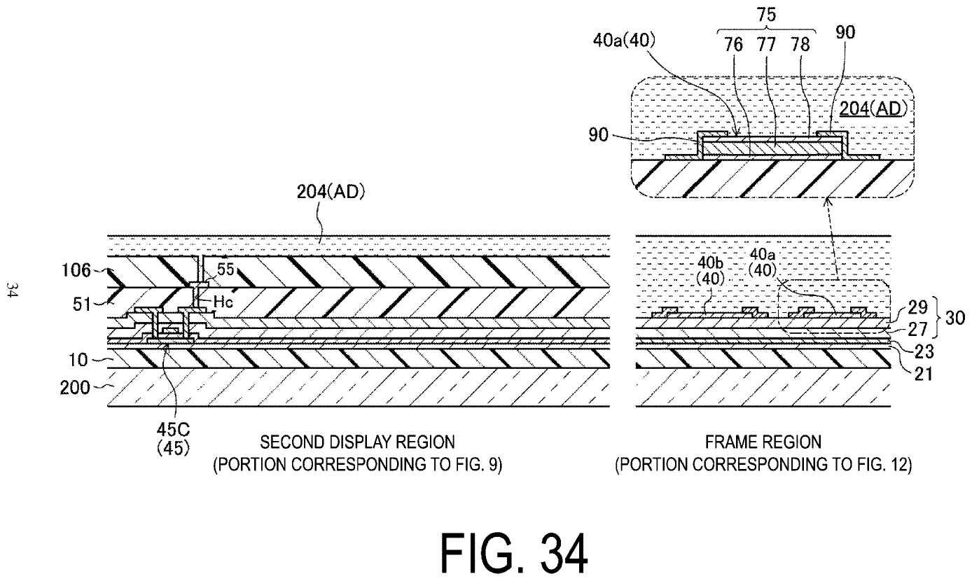

In the organic EL display device 1 according to the third embodiment, the protection film 90 is formed in the same layer and formed of the same material as the passivation film 96 located in a layer below the second flattening film 52. Thereby, as illustrated in FIG. 34, the first metal layers 77 of the first frame wiring line 40a and the second frame wiring line 40b can be suitably protected from an alkaline developing solution 204 used for developing the coating film 106 of the photosensitive resin forming the second flattening film 52.

In the organic EL display device 1 according to the third embodiment, the lower layer partial wiring line 55 is covered with the passivation film 96. Thereby, the organic insulating film covering the lower layer partial wiring line 55 in the multilayer structure 58, that is, the second flattening film 52 in this example can be omitted. The protection film 90 is formed in the same layer and formed of the same material as the passivation film 96. Accordingly, the protection film 90 can be formed by patterning the same film as the passivation film 96 at the same time. The process of forming the organic insulating film is higher in cost than the process of forming an inorganic insulating film. For this reason, this is advantageous to reduce the cost of the organic EL display device 1.

In the organic EL display device 1 according to the third embodiment, the passivation film 96 is provided only in a region overlapping the lower layer partial wiring line and on the periphery thereof. When the passivation film 96 is provided on the entire surface of the first flattening film 51 and also serves as the protection film 90, moisture and gas between the layers and in the layers that constitute the organic EL display device 1 are prevented from escaping in the manufacturing process of the organic EL display device 1. On the other hand, when the passivation film 96 is locally provided at a necessary position as in this example, it is advantageous in preventing moisture and gas between the layers and in the layers that constitute the organic EL display device 1 from being prevented from escaping.

### First Modification Example

In the organic EL display device 1 according to the first embodiment, the first frame wiring line 40a and the second frame wiring line 40b may be formed in the same layer and formed of the same material as the power supply wiring line 40p, the source wiring line 40s, and the upper layer pull-out wiring line 42. The same applies to the organic EL display devices 1 according to the second embodiment and the third embodiment.

In the case of this example, the first frame wiring line 40a and the second frame wiring line 40b are located in a layer below the entirety of the multilayer structure 58 and are exposed from the first flattening film 51, the second flattening film 52, and the third flattening film 53. In addition, the power supply wiring line 40p, the source wiring line 40s, and the upper layer pull-out wiring line 42 are composed of the same layered film (the third metal layer 76, the first metal layer 77, and the second metal layer 78) as the first frame wiring line 40a and the second frame wiring line 40b.

### Second Modification Example

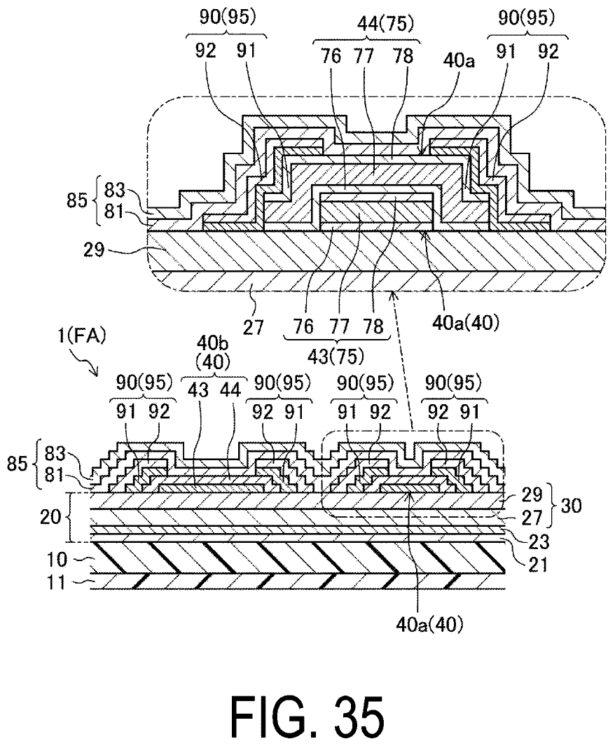

As illustrated in FIG. 35, in the organic EL display device 1 according to the first embodiment, the first frame wiring line 40a and the second frame wiring line 40b may be formed by layering the first wiring line layer 43 and the second wiring line layer 44 in this order on the second interlayer insulating film 29. The same applies to the organic EL display devices 1 according to the second embodiment and the third embodiment.

For example, the first wiring line layer 43 is formed in the same layer and formed of the same material as the power supply wiring line 40p, the source wiring line 40s, and the upper layer pull-out wiring line 42. The second wiring line layer 44 is provided to cover the first wiring line layer 43 including the end surface thereof in the width direction. For example, the second wiring line layer 44 is formed in the same layer and formed of the same material as the lower layer partial wiring line 55.

Each of the pair of protection films 90 provided for the first frame wiring line 40a is formed to cover a range from the surface of the second interlayer insulating film 29 to the side end surface of the second wiring line layer 44 and to extend over the upper surface of the second wiring line layer 44. Each of the pair of protection films 90 provided for the second frame wiring line 40b is also formed to cover a range from the surface of the second interlayer insulating film 29 to the side end surface of the second wiring line layer 44 and to extend over the upper surface of the second wiring line layer 44.

### Third Modification Example

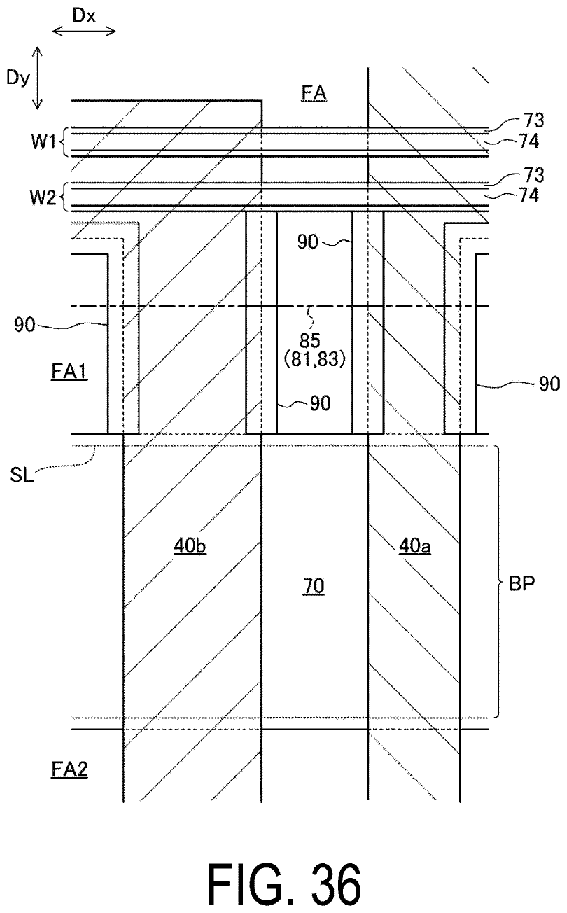

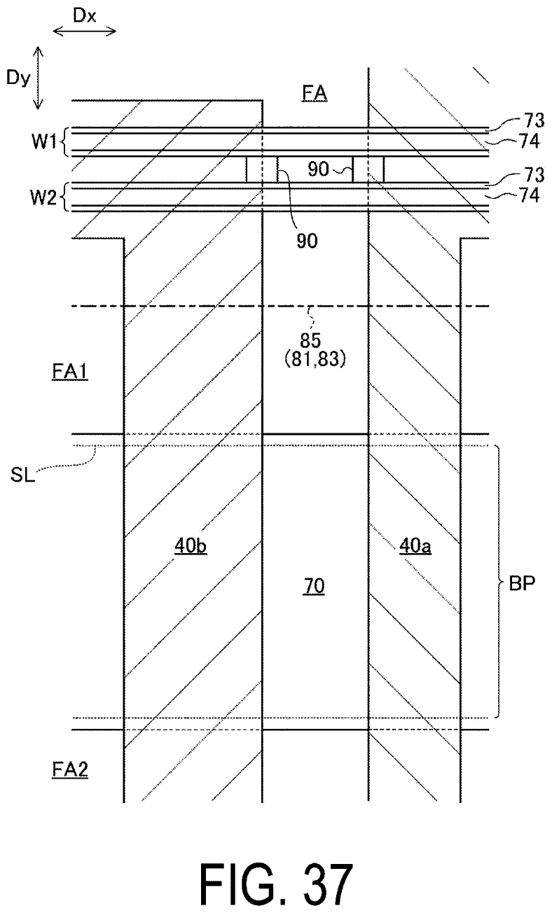

As illustrated in FIG. 36, in the organic EL display devices 1 according to the first to third embodiments, the protection film 90 may be provided only in a portion between the second dam wall W2 and the bending portion BP in the frame region FA. In addition, as illustrated in FIG. 37, in the organic EL display devices 1 according to the first to third embodiments, the protection film 90 may be provided only in a portion between the first dam wall W1 and the second dam wall W2 in the frame region FA.

### Other Embodiments

In the first embodiment, each of the first flattening film 51, the second flattening film 52, and the third flattening film 53 is formed using a positive photosensitive resin, but the disclosure is not limited thereto. Each of the first flattening film 51, the second flattening film 52, and the third flattening film 53 may be formed using a negative photosensitive resin. This also applies to the second and third embodiments.

In the first embodiment, in the first dam wall W1 and the second dam wall W2, the first wall layer 73 and the second wall layer 74 are formed in the same layer and formed of the same material as the second flattening film 52 and the edge cover 66, respectively. However, the disclosure is not limited thereto. The first wall layer 73 may be formed in the same layer and formed of the same material as the first flattening film 51, and the second wall layer 74 may be formed in the same layer and formed of the same material as the second flattening film 52 or the third flattening film 53. The first wall layer 73 may also be formed in the same layer and formed of the same material as the third flattening film 53.

In the first embodiment, a case where the first dam wall W1 and the second dam wall W2 have a two-layer structure has been exemplified, but the disclosure is not limited thereto. The first dam wall W1 and the second dam wall W2 may have a structure of three or more layers. Furthermore, the first dam wall W1 and the second dam wall W2 may differ in the number of layers. Furthermore, the first dam wall W1 and the second dam wall W2 may be designed at different heights.

In the first to third embodiments, the plurality of organic EL elements 65 provided in the light-emitting element region EA are grouped into sets of two organic EL elements 65, and the two organic EL elements 65 in each set are connected to each other via the upper layer partial wiring line 57, but the disclosure is not limited thereto. The plurality of organic EL elements 65 in the light-emitting element region EA may be grouped into sets of three or more organic EL elements 65, and the organic EL elements 65 in each set may be connected to each other via the upper layer partial wiring line 57.

Two or more organic EL elements 65 of the plurality of organic EL elements 65 provided in the light-emitting element region EA may not form one set. That is, the plurality of organic EL elements 65 in the light-emitting element region EA may not be connected to each other and may be individually controlled. In this case, in the circuit arrangement region CA, a separate pixel circuit PC is provided for each organic EL element 65, and each organic EL element 65 is connected to the separate pixel circuit PC via the connection wiring line 40r.

In the first to third embodiments, the organic EL layer 62 is provided individually in each of the subpixels SP, but the disclosure is not limited thereto. The organic EL layer 62 may be continuously provided in common to the plurality of subpixels SP. In this case, the organic EL display device 1 may include a color filter, for example, to perform color tone expression in each of the subpixels SP.

In the first to third embodiments, each of the pixels PX is composed of the subpixels SP of three colors, but the disclosure is not limited thereto. The subpixels SP that constitutes each pixel PX may have four or more colors. The subpixels SP of three colors that constitute each pixel PX are provided in a stripe array, but the disclosure is not limited thereto. The array of the plurality of subpixels PS may be another array such as a PenTile array.

In the first to third embodiments, the plurality of TFTs 45 that constitutes the pixel circuit PC are three, namely, the first TFT 45A, the second TFT 45B and the third TFT 45C, but the disclosure is not limited thereto, and the number of TFTs 45 that constitutes the pixel circuit PC may be two or less, or four or more. In addition, each TFT 45 may be configured as a bottom gate type.

In the first to third embodiments, the pixel electrode 61 is an anode, and the common electrode 63 is a cathode, but the disclosure is not limited thereto. The organic EL display device 1 may be configured such that the pixel electrode 61 functions as a cathode and the common electrode 63 functions as an anode. In this case, the organic EL layer 62 has an inverted layered structure.

In the first to third embodiments, the organic EL layer 62 has a five-layer structure including a hole injection layer, a hole transport layer, a light-emitting layer, an electron transport layer, and an electron injection layer, but the disclosure is not limited thereto. The organic EL layer 62 may have a three-layer structure including a hole injection layer and hole transport layer, a light-emitting layer, and an electron transport layer and electron injection layer, and may adopt any layered structure.

In the first to third embodiments, the substrate of the organic EL display device 1 is the substrate layer 10, but the disclosure is not limited thereto. As the substrate, it is possible to use a substrate made of an arbitrary material as long as it has light transmittance, such as a plastic substrate made of polyethylene terephthalate (PET) or a glass substrate.

In the first to third embodiments, the camera 3 has been exemplified as an electronic component that can be combined with the organic EL display device 1, but the disclosure is not limited thereto. The electronic component mentioned above may be another electronic component such as a fingerprint sensor, a face recognition sensor, or a luminance sensor as long as the electronic component is disposed in a position overlapping the second display region DA2 on the back face side of the organic EL display device 1, and configured to utilize light transmitted through the display region DA.

In the first to third embodiments, the organic EL display device 1 has been exemplified as the display device according to the disclosure, but the disclosure is not limited thereto. The technology of the disclosure can be applied to a display device provided with a plurality of light-emitting elements to be driven by a current. Examples of the display device include a display device including a Quantum-dot light-emitting diode (QLED), which is a light-emitting element using a quantum dot-containing layer. In addition, the technology of the disclosure is also applicable to a liquid crystal display device and a plasma display device.

The preferred embodiments have been described above as examples of the technology of the disclosure. However, the technology of the disclosure is not limited thereto, and is also applicable to an embodiment in which modification, replacement, adding, omission, and the like are suitably made. It is understood by those skilled in the art that various modification examples can be made to the above embodiment without departing from the spirit of the technology of the disclosure, and such modification examples also belong to the scope of the technology of the disclosure.

### INDUSTRIAL APPLICABILITY

As described above, the disclosure is useful for a display device.

1. A display device comprising:
a display region in which an image is displayed; and
a frame region provided around the display region,
wherein the display region is provided with a light-emitting element, a pixel circuit configured to control light emission of the light-emitting element, and a connection wiring line connecting the pixel circuit and the light-emitting element,
the connection wiring line includes a plurality of partial wiring lines formed in different layers with a corresponding one of a plurality of organic insulating films interposed between adjacent ones of the plurality of partial wiring lines,
the plurality of partial wiring lines and the plurality of organic insulating films constitute a multilayer structure in which the plurality of partial wiring lines and the plurality of organic insulating films are alternately layered,
the frame region is provided with a frame wiring line that is located in a layer below a part or entirety of the multilayer structure and is exposed from the organic insulating films, and an inorganic insulating film that is located in a layer above the multilayer structure and covers the frame wiring line,
the frame wiring line is composed of a layered film in which a first metal layer made of any one of metals of aluminum, copper, silver, and gold or an alloy of any of the metals and a second metal layer made of any one of metals of titanium, molybdenum, chromium, and tantalum or an alloy of any of the metals are sequentially layered, and
a protection film is provided in a layer below the inorganic insulating film in a manner that the protection film covers an end surface of the frame wiring line in a width direction.

2. The display device according to claim 1,
wherein a part or entirety of the frame wiring line is formed in the same layer and formed of the same material as a lower layer partial wiring line located in a lower layer among the plurality of partial wiring lines.

3. The display device according to claim 1,
wherein the display region is provided with a signal wiring line through which a signal is supplied to the pixel circuit, and
a part or entirety of the frame wiring line is formed in the same layer and formed of the same material as the signal wiring line.

4. The display device according to claim 1,
wherein the protection film is formed in the same layer and formed of the same material as a partial wiring line in at least one layer of the plurality of partial wiring lines.

5. The display device according to claim 4,
wherein the protection film is composed of a layered film in which a plurality of first conductive layers are layered, and
each of the plurality of first conductive layers is formed in the same layer and formed of the same material as a corresponding one of the plurality of partial wiring lines provided in the different layers.

6. The display device according to claim 1,
wherein the light-emitting element includes a pixel electrode provided for a corresponding one of a plurality of subpixels included in the display region,
the inorganic insulating film is provided in a layer above the pixel electrode, and
the protection film includes a second conductive layer formed in the same layer and formed of the same material as the pixel electrode.

7. The display device according to claim 1,
wherein the protection film is formed of an inorganic insulating material.

8. The display device according to claim 7,
wherein a lower layer partial wiring line located in a lower layer among the plurality of partial wiring lines is covered with an interlayer insulating film, and
the protection film is formed in the same layer and formed of the same material as the interlayer insulating film.

9. The display device according to claim 8,
wherein the interlayer insulating film is provided only in a position overlapping the partial wiring lines and on a periphery of the partial wiring lines in a plan view.

10. The display device according to claim 1,
wherein the protection film is provided only in a position overlapping the frame wiring line and on a periphery of the frame wiring line in a plan view.

11. The display device according to claim 1,
wherein the protection film is provided at both end portions of the frame wiring line in the width direction and exposes a central portion of the frame wiring line in the width direction.

12. The display device according to claim 1,
wherein the frame wiring line is a power supply trunk line through which a voltage is applied to the light-emitting element, and
a conductivity of the first metal layer is higher than a conductivity of the second metal layer.

13. The display device according to claim 1,
wherein the display region is provided with a sealing film sealing a plurality of the light-emitting elements,
the sealing film includes an organic film formed by applying a liquid material,
a dam wall that dams the liquid material is provided, in the frame region, in a frame shape in a manner that the dam wall surrounds the display region,
the frame wiring line is provided in a layer below the dam wall and extends overlapping the dam wall in a plan view, and
the protection film is provided in a region not overlapping the dam wall in a plan view.

14. The display device according to claim 1, further comprising:
an electronic component that is disposed in a position on a back face side overlapping the display region in a plan view and uses external light transmitted through the display region,
wherein the display region includes a first display region and a second display region that is provided inside the first display region and transmits light to be used by the electronic component, and
some of the partial wiring lines are made of a transparent conductive material having light transmittance.

15. The display device according to claim 14,
wherein the transparent conductive material is indium tin oxide.

16. The display device according to claim 14,
wherein the second display region includes a light-emitting element region in which a plurality of the light-emitting elements are disposed,
the pixel circuit configured to control light emission of the light-emitting elements disposed in the light-emitting element region is provided around the light-emitting element region, and
the plurality of partial wiring lines provided in the different layers intersect each other with a corresponding one of the organic insulating films interposed between adjacent ones of the partial wiring lines, in the light-emitting element region.

17. The display device according to claim 14,
wherein the electronic component is a camera.

18. The display device according to claim 1,
wherein a base insulating film is provided in the frame region,
the frame wiring line includes a third metal layer formed on a surface of the base insulating film and is a layered film in which the first metal layer and the second metal layer are layered in order on the third metal layer, and
the third metal layer has higher adhesion to the base insulating film than the first metal layer.

19. The display device according to claim 18,
wherein the first metal layer is formed of aluminum or an aluminum alloy, and
the second metal layer and the third metal layer are formed of titanium or a titanium alloy.

20. The display device according to claim 1,
wherein the light-emitting element is an organic electroluminescence element.
